(19) United States
(12) Patent Application Publication
(10) Pub. No.: US 2025/0287125 A1
(43) Pub. Date: Sep. 11, 2025

(54) SEMICONDUCTOR STRUCTURE AND METHOD OF MANUFACTURING THE SAME

(71) Applicant: Taiwan Semiconductor Manufacturing Company, Ltd., Hsinchu (TW)

(72) Inventors: Chih-Min Liu, Zhubei City (TW); Feng-Wei Kuo, Zhudong Township (TW); Yi-Hsien Chang, Shetou Township (TW); Chi-Hsien Chung, New Taipei City (TW); Tzu-Jui Wang, Fengshan City (TW); Chen-Jong Wang, Hsin-Chu (TW); Dun-Nian Yaung, Taipei City (TW)

(21) Appl. No.: 19/211,861

(22) Filed: May 19, 2025

Related U.S. Application Data
(63) Continuation-in-part of application No. 17/887,634, filed on Aug. 15, 2022.
(60) Provisional application No. 63/342,659, filed on May 17, 2022.
(60) Provisional application No. 63/662,427, filed on Jun. 21, 2024.

(51) Int. Cl. H04N 25/79; G01N 27/414; H01L 23/00; H04N 25/709; H04N 25/77; H10F 39/00; H10F 39/18

(52) U.S. Cl. CPC H04N 25/79; G01N 27/4145; G01N 27/4148; H01L 24/08; H04N 25/709; H04N 25/77; H10F 39/182; H10F 39/809; H01L 2224/08145

(57) ABSTRACT

Various embodiments of the present disclosure are directed to a semiconductor structure in which circuit components of the semiconductor structure are split amongst various IC dies, which are configured to receive different voltages to reduce noise and/or enhanced performance. As an example, a first integrated circuit (IC) die includes a first semiconductor substrate, and a second IC die includes a second semiconductor substrate. A pixel includes a sensor in the first IC die and a pixel circuit in the second IC die. The pixel circuit includes a plurality of transistors, the sensor includes a first terminal and a second terminal that are both in the first semiconductor substrate, the first terminal is electrically coupled to an input of the pixel circuit, and the second terminal is electrically isolated from individual transistor bodies of the plurality of transistors.

### REFERENCE TO RELATED APPLICATION

This Application claims the benefit of U.S. Provisional Application No. 63/662,427, filed on Jun. 21, 2024, and is a Continuation-in-Part of U.S. application Ser. No. 17/887,634, filed on Aug. 15, 2022, which claims the benefit of U.S. Provisional Application No. 63/342,659, filed on May 17, 2022, the contents of each of these Applications are hereby incorporated by reference in their entirety.

### BACKGROUND

The semiconductor manufacturing industry continuously seeks to increase functional density. Traditionally, functional density has been increased by scaling down circuit components. However, it is becoming increasingly difficult to continue scaling down circuit components. Therefore, advanced packaging techniques and chip stacking are increasingly employed to increase functional density. Further, as circuit components are scaled down, supply voltage is generally reduced. This reduces power consumption but may be incompatible with or otherwise degrade performance for certain types of circuit components.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of various features may be arbitrarily increased or reduced for clarity of discussion.

FIG. 1 illustrates a circuit diagram of some embodiments of an image sensor that spans three integrated circuit (IC) dies, according to aspects of the present disclosure.

FIGS. 2A-2C illustrate various circuit diagrams of some alternative embodiments of the image sensor of FIG. 1.

FIGS. 3A and 3B illustrate various circuit diagrams of some embodiments of the image sensors of FIGS. 1 and 2A-2C in which a current source and an analog-to-digital converter (ADC) further comprise individual transistors.

FIG. 4 illustrates a cross-sectional view of some embodiments of the image sensor of FIG. 1.

FIG. 5 illustrates a plan view of some embodiments of the image sensor of FIG. 4.

FIG. 6 illustrates a circuit diagram of some embodiments of an image sensor that spans two IC dies, according to aspects of the present disclosure.

FIGS. 7A-7C illustrate various circuit diagrams of some alternative embodiments of the image sensor of FIG. 6.

FIGS. 8A and 8B illustrate various circuit diagrams of some embodiments of the image sensors of FIGS. 6 and 7A-7C in which a current source and an ADC further comprise individual transistors.

FIG. 9 illustrates a cross-sectional view of some embodiments of the image sensor of FIG. 6.

FIG. 10 illustrates a plan view of some embodiments of the image sensor of FIG. 9.

FIGS. 11A and 11B illustrate various diagrams of some embodiments of an image sensor comprising a plurality of pixels, according to aspects of the present disclosure.

FIG. 12 illustrates a circuit diagram of some embodiments of a biosensor that spans three IC dies, according to aspects of the present disclosure.

FIGS. 13A-13G illustrate various circuit diagrams of some alternative embodiments of the biosensor of FIG. 12.

FIG. 14 illustrates a circuit diagram of some embodiments of the biosensor of FIG. 12 in which a controller and an ADC further comprise individual transistors.

FIG. 15 illustrates a cross-sectional view of some embodiments of the biosensor of FIG. 12.

FIGS. 16A and 16B illustrate cross-sectional views of some embodiments of a first IC die, a second IC die, and third IC die in the biosensor of FIG. 15.

FIG. 17 illustrates a plan view of some embodiments of the first IC die of FIGS. 16A and 16B.

FIG. 18 illustrates a cross-sectional view of some alternative embodiments of the biosensor of FIG. 15.

FIG. 19 illustrates a cross-sectional view of some embodiments of a first IC die, a second IC die, and a third IC die in the biosensor of FIG. 18.

FIG. 20 illustrates a cross-sectional view of some alternative embodiments of the biosensor of FIG. 15.

FIGS. 21A and 21B illustrate cross-sectional views of some embodiments of a first IC die, a second IC die, and third IC die in the biosensor of FIG. 20.

FIG. 22 illustrates a circuit diagram of some embodiments of a biosensor that spans two IC dies, according to aspects of the present disclosure

FIGS. 23A-23E illustrate various circuit diagrams of some alternative embodiments of the biosensor of FIG. 22.

FIG. 24 illustrates a circuit diagram of some embodiments of the biosensor of FIG. 22 in which a controller and an ADC further comprise individual transistors.

FIG. 25 illustrates a cross-sectional view of some embodiments of the biosensor of FIG. 22.

FIG. 26 illustrates a cross-sectional view of some embodiments of a first IC die and a second IC die in the biosensor of FIG. 25.

FIGS. 27A and 27B illustrate various diagrams of some embodiments of a biosensor comprising a plurality of pixels, according to aspects of the present disclosure.

FIG. 28 illustrates a block diagram of some embodiments of a method of use according to aspects of the present disclosure

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

A semiconductor structure may include various different types of circuit components formed in one or more integrated circuit (IC) dies. Such circuit components may, for example, include memory cells, photodetectors, transistors, etc. Further, the various different types of circuit components may depend on different supply voltages. Therefore, as the semiconductor structure is scaled down and supply voltage is reduced, challenges may arise.

Take a complementary metal-oxide semiconductor (CMOS) image sensor (CIS) as an example. The CIS may comprise a first IC die and a second IC die that are stacked and bonded together. The first IC die accommodates an array of pixels, each comprising a photodetector and a pixel circuit, whereas the second IC die accommodates an application-specific integrated circuit (ASIC) common to and electrically coupled individually to the pixels. As the CIS is scaled down, supply voltage may be reduced. However, this may prevent the full transfer of charge from photodetectors to corresponding floating diffusion nodes (FDNs), which may negatively impact quantum efficiency (QE) of the CIS.

To counter the decrease in supply voltage from the scaling down, a semiconductor structure may employ different reference voltages at different IC dies. For example, continuing with the CIS example, the first IC die may have a negative reference voltage, whereas the second IC die may have a reference voltage that is ground. The negative reference voltage effectively increases the supply voltage at the photodetector to improve charge transfer. However, using different reference voltages at different IC dies may cause noise across the semiconductor structure due to non-tracking between the two reference voltages.

Various embodiments of the present disclosure are directed towards a semiconductor structure in which circuit components of the semiconductor structure are split amongst various IC dies, which are configured to receive different supply and/or reference voltages. Further, the circuit components are arranged within the various IC dies so minimum supply voltages to the circuit components are met and so noise is reduced.

As an example, a CIS may comprise photodetectors, corresponding pixel circuits, and an ASIC. The photodetectors may be in a first IC die. The pixel circuits may be split amongst the first IC die and a second IC die with transfer transistors of the pixel circuits being in the first IC die and remaining pixel transistors of the pixel circuits being in the second IC die. The ASIC may be in the second IC die or, alternatively, may be in a third IC die separated from the first IC die by the second IC die. Further, the first IC die may have a negative reference voltage, whereas the second IC die and, where present, the third IC die may have a reference voltage that is ground. The negative reference voltage effectively increases the supply voltage at the photodetectors to allow full charge transfer from the photodetectors.

The portions of the pixel circuits in the second IC die are responsible for generating the signals that are output from the pixel circuits to the ASIC. Because these portions have the same reference voltage as the ASIC, there is no non-tracking reference noise passing between the pixel circuits and the ASIC. Hence, QE of the CIS is improved.

With reference to FIG. 1, a circuit diagram 100 of some embodiments of an image sensor spanning three IC dies, according to aspects of the present disclosure, is provided. The image sensor may, for example, be a CIS or some other suitable type of image sensor. The image sensor includes a first IC die 1, a second IC die 2, and a third IC die 3 that are stacked with the second IC die 2 being between and bonded to the first and third IC dies 1, 3. Further, the second IC die 2 is electrically coupled to the first and third IC dies 1, 3 respectively by a first interconnect structure 41 and a second interconnect structure 42.

A pixel PX spans the first and second IC dies 1, 2 and comprises a pinned photodiode 10 and a pixel circuit 20. In alternative embodiments, the pinned photodiode 10 is some other suitable type of photodetector. The pinned photodiode 10 is in the first IC die 1, and the pixel circuit 20 is in both the first IC die 1 and the second IC die 2.

The pixel circuit 20 is configured to facilitate reset and readout of the pinned photodiode 10. Further, the pixel circuit 20 comprises a transfer transistor 11 in the first IC die 1 and a plurality of additional pixel transistors (e.g., transistors 21, 22, and 23) in the second IC die 1. The transfer transistor 11 forms a first pixel-circuit portion 20f, whereas the plurality of additional pixel transistors form a second pixel-circuit portion 20s.

The transfer transistor 11 is electrically coupled from a cathode C₁₀ of the pinned photodiode 10 to a FDN. Further, an anode A₁₀ of the pinned photodiode 10 and a body B₁₁ of the transfer transistor 11 are electrically coupled together and configured to receive a first reference voltage V1. In some embodiments, reference voltage as used herein may also be referred to as ground level, ground point, or the like. The transfer transistor 11 is configured to selectively transfer charge that accumulates at the pinned photodiode 10 to the FDN.

The second pixel-circuit portion 20s is electrically coupled to the FDN (more generally, the first pixel-circuit portion 20f) via the first interconnect structure 41. Further, individual transistor bodies (e.g., body B₂₁, body B₂₂, and body B₂₃) of the second pixel-circuit portion 20s are electrically coupled together (e.g., via a substrate of the second IC die 2) and are configured to receive a second reference voltage V2. The second pixel-circuit portion 20s is configured to reset the FDN and the pinned photodiode 10 and to generate an output signal based on the amount of charge transferred to the FDN.

An ASIC 30 is in the third IC die 3 and electrically coupled to the pixel circuit 20 by the second interconnect structure 42. The ASIC 30 may, for example, provide control over operation of the pixel PX and/or may, for example, perform analog-to-digital conversion (ADC), image signal processing, and the like on an output of the pixel circuit 20. The ASIC 30 comprises an ADC 31 and a current source 32. The ADC 31 and the current source 32 (more generally the ASIC 30) are configured to receive the second reference voltage V2. For example, the ADC 31 and the current source 32 may comprise individual transistors with individual bodies configured to receive the second reference voltage V2.

In some embodiments, the pinned photodiode 10 may be generalized as a sensor or the like. In some embodiments, the pixel circuit 20 may be generalized as an interface circuit for the sensor. In some embodiments, the ASIC 30 may be generalized as a control and/or processing circuit for the interface circuit and/or the sensor.

Performance of the ADC 31 may be characterized by its signal-to-noise ratio (SNR). Further, it has been appreciated that different reference voltages (e.g., ground levels) respectively at the second pixel-circuit portion 20s and the ASIC 30 may significantly degrade the SNR. For example, supposing the second pixel-circuit portion 20s had the first reference voltage V1 and the ASIC 30 had the second reference voltage V2, noise may arise and degrade the SNR.

A reference voltage (more generally any voltage) is subject to (random) variations. Such variations may, for example, correspond to stray voltages and/or may, for example, arise from the resistance of bond wires, conductive traces, etc. in the IC dies. With different reference voltages, the variations in one reference voltage are different than, and hence don't track, the variations in the one or more other reference voltages. This non-tracking leads to noise that negatively affects the performance (e.g., the SNR) of the ADC 31.

Because the second pixel-circuit portion 20s and the ADC 31 are configured to receive the second reference voltage V2 (e.g., the same reference voltage), these circuit components have the same reference voltage. Hence, the ADC 31 has the same reference-voltage variations as the second pixel-circuit portion 20s. This prevents noise induced by different reference voltages respectively at the second pixel-circuit portion 20s and the ASIC 30 and enhances the performance of the ADC 31.

In some embodiments, the first reference voltage V1 is negative, whereas the second reference voltage V2 is ground or otherwise greater than the first reference voltage V1. For example, the first reference voltage V1 may be −1.3 volts (V), whereas the second reference voltage V2 may be 0V. Other suitable voltages are, however, amenable. As a result, the pinning voltage of the pinned photodiode 10 and the turn-on voltage of the transfer transistor 11 are relative to the first reference voltage V1 rather than the second reference voltage V2. This effectively increases these voltages (e.g., pinning voltage et al.) by a magnitude of the potential difference between the first and second reference voltages V1, V2.

The affective increase in voltages at the pinned photodiode 10 and the transfer transistor 11 allows the supply voltage to be reduced and/or performance of the image sensor to be enhanced. For example, the reduced supply voltage reduces power consumption and may, for example, coincide with scaling down of the image sensor. As another example, the increased pinning voltage increases the full well capacity (FWC) of the pinned photodiode 10, whereas the increased turn-on voltage allows full transfer of charge from the pinned photodiode 10 to the FDN, to collectively enhance the performance of the image sensor.

With continued reference to FIG. 1, the pinned photodiode 10 is configured to convert radiation that enters the image sensor to an electrical signal. When incident light (containing photons of sufficient energy) strikes the pinned photodiode 10, an electron-hole pair is created. The pinned photodiode 10 includes the cathode C₁₀ and the anode A₁₀. Further, the pinned photodiode 10 is connected to the transfer transistor 11.

The transfer transistor 11 includes a gate G₁₁, a source S₁₁, a drain D₁₁, and the body B₁₁. In some embodiments, the transfer transistor 11 may be an n-channel metal-oxide-semiconductor (NMOS) transistor. The source S₁₁ is connected to the cathode is C₁₀ of the pinned photodiode 10, and the body B₁₁ is connected to the anode A₁₀ of the pinned photodiode 10. As noted above, the anode A₁₀ and the body B₁₁ are configured to receive the first reference voltage V1. For example, the first reference voltage V1 may be applied to the anode A₁₀ and the body B₁₁ to bias the anode A₁₀ and the body B₁₁ with the first reference voltage V1. The first reference voltage V1 may, for example, be negative.

The transfer transistor 11 is turned ON when a high voltage is applied onto the gate G₁₁, while the transfer transistor 11 is turned OFF when a low voltage is applied onto the gate G₁₁. The high and low voltages may, for example, correspond to voltages respectively above and below a threshold voltage of the transfer transistor 11. By biasing the anode A₁₀ and the body B₁₁ with a negative voltage, the ground level of the transfer transistor 11 is more negative than when biased at 0V (ground). Thus, the voltage applied to the gate G₁₁ may be lower to comply with the lower supply voltages, which reduce power consumption.

The drain D₁₁ of the transfer transistor 11 is a FDN of the pixel PX. The FDN is configured to store charges (or carriers) transferred from the pinned photodiode 10 through a channel of the transfer transistor 11. The potential of the FDN is monitored by a source-follower transistor 22 of second pixel-circuit portion 20s.

The pinned photodiode 10 is included in a substrate of the first IC die 1. Further, the transfer transistor 11 is included on the substrate. The substrate is configured to receive the first reference voltage V1. For example, the first reference voltage V1 may be applied to a bulk region of the substrate to bias the first substrate. In some embodiments, an array of pinned photodiodes, including the pinned photodiode 10, is in the substrate. Further, in some embodiments, an array of transfer transistors, including the transfer transistor 11, is on the first substrate and each transfer transistor controls one of the pinned photodiodes.

In some embodiments, the pinned photodiode 10 may be formed by a heavily-doped capping layer with a first dopant type, a lightly-doped buried layer with a second dopant type, and a lightly doped bottom layer with the first dopant type. In some embodiments, the first dopant type is a p-type and the second dopant type is n-type. The pinned photodiode 10 may have a p+np vertical structure in the substrate of the first IC die 1.

The second pixel-circuit portion 20s comprises a reset transistor 21, the source-follower transistor 22, and a row-select transistor 23. Alternatively, there may be more or less transistors. The reset transistor 21 includes a gate G₂₁, a source S₂₁, a drain D₂₁, and a body B₂₁ and is connected to the transfer transistor 11 and the source-follower transistor 22. The source-follower transistor 22 includes a gate G₂₂, a source S₂₂, a drain D₂₂, and a body B₂₂ and is connected to the row-select transistor 23. The row-select transistor 23 includes a gate G₂₃, a source S₂₃, a drain D₂₃, and a body B₂₃ and is connected to the ASIC 30.

The gate G₂₁ of the reset transistor 21 is configured to receive a control signal (e.g., from the ASIC 30) to control the state of the reset transistor 21. When ON, the reset transistor 21 resets the FDN by pulling it to a supply voltage V_{DD}. In alternative embodiments, the reset transistor 21 may pull the FDN to some other suitable voltage. When OFF, the reset transistor 21 has no influence on the potential of the FDN.

The source S₂₁ of the reset transistor 21 is connected to the FDN and the gate G₂₂ of the source-follower transistor 22. The body B₂₁ of the reset transistor 21 is configured to receive the second reference voltage V2. For example, the second reference voltage V2 may be applied to the body B₂₁. As above, the second reference voltage V2 is different than and independent of the first reference voltage V1. Further, the second reference voltage V2 is not tracked by the first reference voltage V1. The second reference voltage V2 may, for example, be higher than the first reference voltage V1 and/or may, for example, be 0V or ground.

The gate G₂₂ of the source-follower transistor 22 is connected to the drain D₁₁ of the transfer transistor 11 via the first interconnect structure 41. As a result, the source-follower transistor 22 may monitor potential at the FDN. The drain D₂₂ of the source-follower transistor 22 is applied with the supply voltage V_{DD}. The source S₂₂ of the source-follower transistor 22 is connected to the drain D₂₃ of the row-select transistor 23. The body B₂₂ of the source-follower transistor 22 is configured to receive the second reference voltage V2. For example, the second reference voltage V2 may be applied to the body B_{22.}

The gate G₂₃ of the row-select transistor 23 is configured to receive a control signal (e.g., from the ASIC 30) to turn the row-select transistor 23 ON and OFF. When ON, the row-select transistor 23 may output an electrical signal to the ASIC 30 that represents the potential of the FDN. Otherwise, OFF, the row-select transistor 23 may isolate the pixel circuit 20 from the ASIC 30. The drain D₂₃ of the row-select transistor 23 is connected to the source S₂₂ of the source-follower transistor 22, and the source S₂₃ of the row-select transistor 23 is connected to the ASIC 30. In some embodiment, this connection is via is a column bus line (not shown). The body B₂₃ of the row-select transistor 23 is configured to receive the second reference voltage V2. For example, the second reference voltage V2 may be applied to the body B_{23.}

The reset transistor 21, the source-follower transistor 22, and the row-select transistor 23 form the second pixel-circuit portion 20s that controls and processes analog signals of the of the pixel PX. The second pixel-circuit portion 20s is electrically connected to the pinned photodiode 10 (via the transfer transistor 11/the first pixel-circuit portion 20f) and to the ASIC 30. The second pixel-circuit portion 20s has a common transistor body (B₂₁, B₂₂, and B₂₃) that is configured to receive the second reference voltage V2

Further, the reset transistor 21, the source-follower transistor 22, and the row-select transistor 23 are included on a substrate of the second IC die 2. Hence, the second pixel-circuit portion 20s is included on the substrate. The substrate is configured to receive the second reference voltage V2. For example, the second reference voltage V2 may be applied to the substrate to bias the substrate.

As noted above, the ASIC 30 includes the ADC 31 and the current source 32. Other circuit components not shown may also be part of the ASIC 30. In alternative embodiments, the ADC 31 may be some other suitable circuit component. Hence, the ADC 31 may more generally be referred to as an electronic device, electronic component, or the like.

The ADC 31 and the current source 32 have individual first terminals connected to the source S₂₃ of the row-select transistor 23. Further, the ADC 31 and the current source 32 are configured to receive the second reference voltage V2 at individual second terminals. For example, the second reference voltage V2 may be applied to the second terminals. The ADC 31 may be configured to convert analog signals from the pixel circuit 20 to digital signals. In some embodiments, the ADC 31 is further configured to perform pre-conversion processing on the analog signals and/or post-conversion processing on the digital signals.

The ADC 31 and the current source 32 (and more generally the ASIC 30) are included on a substrate of the third IC die 3. The substrate is configured to receive the second reference voltage V2. For example, the second reference voltage V2 may be applied to the substrate to bias the substrate.

As noted above, the pinned photodiode 10 and the first pixel-circuit portion 20f are configured to receive the first reference voltage V1, whereas the second pixel-circuit portion 20s is configured to receive the second reference voltage V2 that is independent of the first reference voltage V1. Further, the first reference voltage V1 is more negative than the second reference voltage V2. This arrangement can achieve complete transfer of charge from the pinned photodiode 10 to the FDN via the transfer transistor 11.

When the pinned photodiode 10 is fully depleted by a prior charge transfer, the pinned photodiode 10 has a pinning voltage Vₚᵢₙ. In a reset mode of the pixel PX, when the transfer transistor 11 is OFF, the FDN is reset by the reset transistor 21 and the potential of the FDN is pulled up to be relatively high (e.g., the supply voltage V_{DD}). In an integration mode of the pixel PX, when the pinned photodiode 10 is isolated from the FDN by the transfer transistor 11, photon-induced carriers (e.g., electrons) are collected and integrated in the pinned photodiode 10. In a charge transfer mode of the pixel PX, when the transfer transistor 11 is applied with a relatively high voltage to turn ON the transfer transistor 11, carriers are transferred from the pinned photodiode 10 to the FDN. In a readout mode of the pixel PX, the charges stored in the FDN are converted to a voltage signal (in a relationship called “conversion gain”) by the source-follower transistor 22 and are subsequently read or processed.

Because the supply voltage V_{DD} used to pull up the potential of the FDN is relative to the second reference voltage V2 (e.g., 0V or ground), whereas potentials at the first IC die 1 are relative to the first reference voltage V1 (e.g., a negative voltage), the potential to which the FDN is pulled up is effectively the supply voltage V_{DD} increased by a magnitude of the potential difference between the first and second reference voltages V1, V2. As a result, an appropriate voltage applied to the gate G₁₁ of the transfer transistor 11 to turn the transfer transistor 11 to a ON can cause a monotonic increase in potential from the pinned photodiode 10 to the floating diffusion node FD. This allows charges from the pinned photodiode 10 to be fully transferred to the FDN and prevents carriers from returning to the pinned photodiode 10.

For example, the potential of the FDN may be lower than the potential of the pinned photodiode 10 when the charges are transferred from the pinned photodiode 10 to the FDN. After the charges are fully transferred, the reverse junction voltage of the pinned photodiode 10, which is fully depleted, may still be larger than the pinning voltage Vₚᵢₙ. Further, the difference between the potential of the FDN and the first reference voltage V1 is larger than the pinning voltage Vₚᵢₙ. This guarantees charge is fully transferred.

In alternatives embodiments, the anode A₁₀ of the pinned photodiode 10, the body B₂₂ of the source-follower transistor 22, and the second terminal of the ADC 31 may be configured to respectively receive the first reference voltage V1, the second reference voltage V2, and a third reference voltage V3 (not shown in FIG. 1). The second reference voltage V2 is tracked by the third reference voltage V3 and independent of the first reference voltage V1. Variation of the first reference voltage V1 is different in volume and/or in time than variation of the second reference voltage V2. However, variation of the second reference voltage V2 is identical in volume and/or in time to variation of the third reference voltage V3 because the third reference voltage V3 tracks the second reference voltage V2.

In some embodiments, all terminals configured to receive the first reference voltage V1 are electrically shorted together and/or electrically shorted to a first conductive pad, whereas all terminals configured to receive the second reference voltage V2 are electrically shorted together and/or electrically shorted to a second conductive pad.

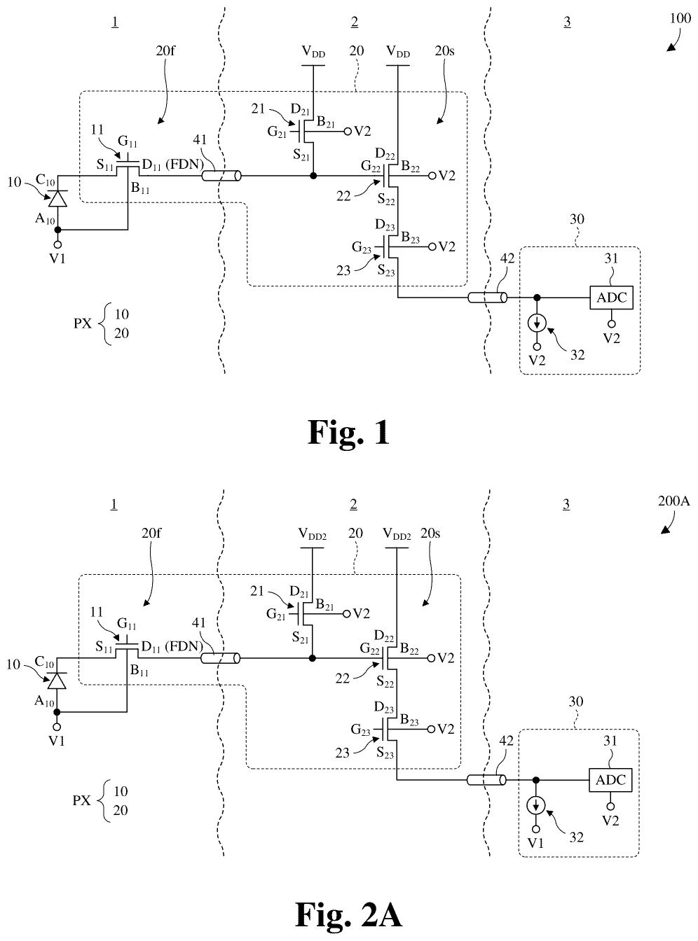

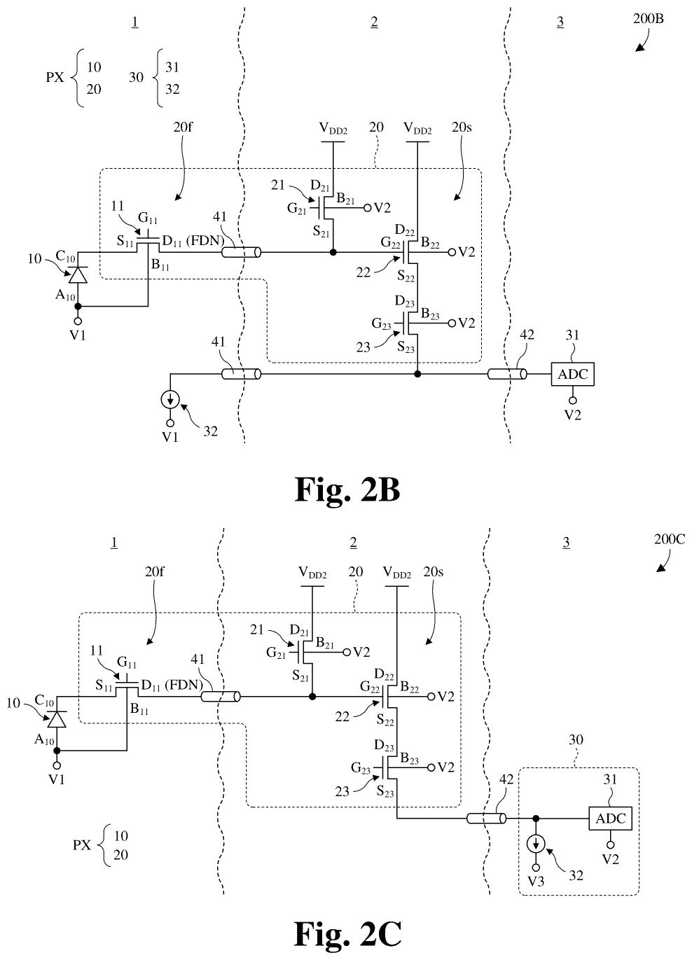

With reference to FIG. 2A, a circuit diagram 200A of some alternative embodiments of the image sensor of FIG. 1 is provided in which the pixel circuit 20 is supplied with a supply voltage V_{DD2} rather than supply voltage V_{DD}. Supply voltage V_{DD2} is less than supply voltage V_{DD}. For example, supply voltage V_{DD2} may be 1.8V, 1.5V, or some other suitable voltage, whereas supply voltage V_{DD} may be 2.8V or some other suitable voltage. Further, the voltage difference between supply voltage V_{DD} and supply voltage V_{DD2} may be equal to or substantially equal to a difference between the first reference voltage V1 (e.g., −1.3V or some other suitable value) and the second reference voltage V2 (e.g., 0V or ground).

As noted above, the difference between the first and second reference voltages V1, V2 affectively increases the voltages at the pinned photodiode 10 and the transfer transistor 11. Because the decrease in supply voltage from supply voltage V_{DD} to supply voltage V_{DD2} is equal to or substantially equal to the difference between the first and second reference voltages V1, V2, the affective increase in voltages at the pinned photodiode 10 and the transfer transistor 11 may be sufficient to allow complete charge transfer from the pinned photodiode 10 to the FDN. For example, the potential difference between the FDN and the pinned photodiode 10 may still have a monotonic increase in potential from the pinned photodiode 10 to the FDN during charge transfer. As such, the pixel PX can fully transfer the charges (carriers) from the pinned photodiode 10 to the FDN. Further, because supply voltage V_{DD2} is lower than supply voltage V_{DD}, the power consumption of the pixel circuit 20 may be reduced.

In some cases, supply voltage V_{DD2} means that the output swing range of the source-follower transistor 22 (or the input swing range of the ADC 31) may be narrower than it would otherwise be with supply voltage V_{DD}. Hence, dynamic range of the source-follower transistor 22 and the ADC 31 may be reduced. However, characteristics of the source-follower transistor 22 may be modified to at least partially regain the dynamic range. For example, the transconductance gₘ of the source-follower transistor 22 may be increased.

Further, the current source 32 may be configured to receive the first reference voltage V1, rather than the second reference voltage V2, to at least partially regain dynamic range. By applying the first reference voltage V1 to the current source 32, the voltage from the drain D₂₂ of the source-follower transistor 22 to the second terminal of the current source 32 is effectively increased by a magnitude of the potential difference between the first and second reference voltages V1, V2. This, in turn, increases the output swing range of the source-follower transistor 22 and the input swing range of the ADC 31.

The current source 32 may have a relatively high effective output resistance. Further, the current source 32 may include a transistor and a decoupling capacitor. The decoupling capacitor may be connected from the gate of the transistor to the source of the transistor to stabilize the gate-to-source voltage (V_{GS}). The relatively high effective output resistance and the stabilization of V_{GS} may provide a constant biasing current and may minimize the noise induced by the variations of the reference voltages.

With reference to FIG. 2B, a circuit diagram 200B of some alternative embodiments of the image sensor of FIG. 2A is provided in which the current source 32 has been moved to the first IC die 1. The current source 32 may be connected to the source-follower transistor 1 through the first interconnect structure 41. The current source 32 may provide a constant biasing current for the source-follower transistor 22. The current source 32 is biased with the first reference voltage V1 (same as the pinned photodiode 10).

The current source 32 may be modified to improve the noise thereof. In such a case, special processes for manufacturing the current source 32 may be applied. That is, special processes may be applied to the manufacture of the current source 32. The current source 32 is disposed on a substrate of the first IC die 1 independent of the substrate of the third IC die 3. The third IC die 3, including the ADC 31, may be manufactured with standard processes, which are mostly fixed in a semiconductor manufacturing fab. The processes for manufacturing the first IC die 1 are relatively flexible as this IC die is for photodiodes. Thus, the current source 32 in the first IC die 1 can be optimized through the adjustment of the manufacturing processes without the constraints from the standard processes of the third IC die 3.

With reference to FIG. 2C, a circuit diagram 200C of some alternative embodiments of the image sensor of FIG. 2A is provided in which the current source 32 is configured to receive a third reference voltage V3 rather than the first reference voltage V1. As noted above, supply voltage V_{DD2} reduces power consumption but also reduces the output swing range of the source-follower transistor 22 (or the input swing range of the ADC 31).

In order to at least partially regain the output swing range of the source-follower transistor 22 (or the input swing range of the ADC 31), the current source 32 may be configured to receive a third reference voltage V3 that is less than the second reference voltage V2. Further, in some embodiments, the third reference voltage V3 is higher than the first reference voltage V1. Because the third reference voltage V3 is higher, the direct-current (DC) biasing for the inputs of the ADC 31 can be higher than it would otherwise be if the current source 32 was biased with the first reference voltage V1. This allows the DC biasing for the input of the ADC 31 to be more compatible with the designed input range of the ADC 31.

In some embodiments, the third reference voltage V3 and the second reference voltage V2 are derived from the same voltage source. Although these reference voltages may be derived from the same voltage source, a voltage divider may introduce variations (or noises), such that the third reference voltage V3 may not track the second reference voltage V2. In order to prevent the variations from affecting the biasing current, the current source 32 may have a relatively high effective output resistance. Further, the current source 32 may include a transistor and a decoupling capacitor connected from the gate of the transistor to the source of the transistor to stabilize the V_{GS}.

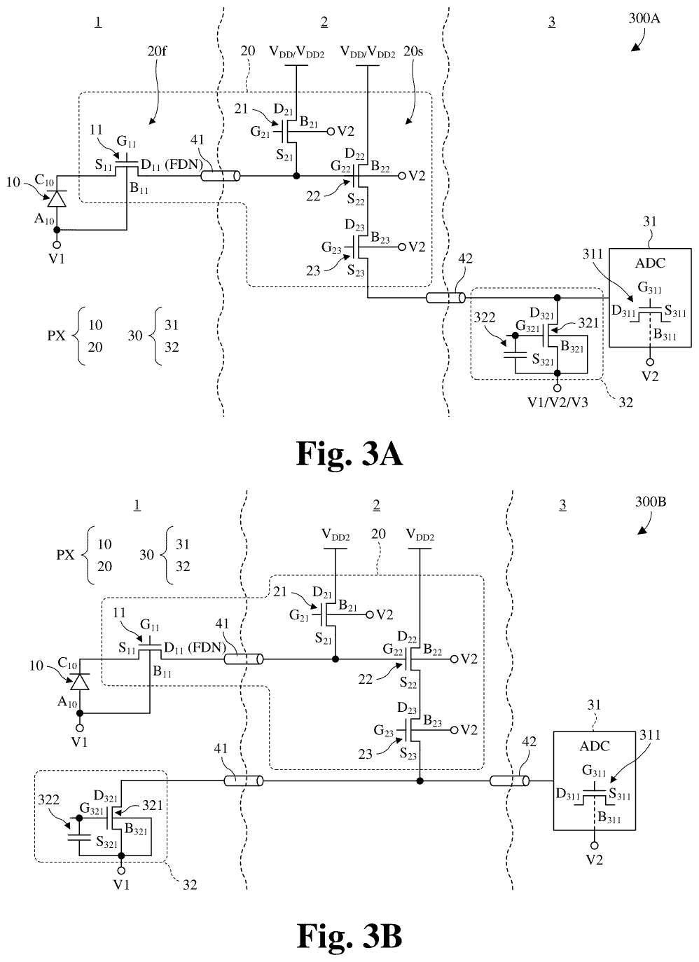

With reference to FIG. 3A, a circuit diagram 300A of some embodiments of the image sensors of FIGS. 1, 2A, or 2C is provided in which the ADC 31 and the current source 32 comprise individual transistors. Further, depending on embodiment of the image sensor, the pixel circuit 20 receives supply voltage V_{DD} or supply voltage V_{DD2}.

The ADC 31 comprises a plurality of transistors 311 (only one of which is shown) that are interconnected to implement functions of the ADC 31. The plurality of transistors 311 comprise individual drains D₃₁₁, individual sources S₃₁₁, individual bodies B₃₁₁, and individual gates G₃₁₁. The individual bodies B₃₁₁ are configured to receive the second reference voltage V2 and are on the substrate of the third IC die 3. Hence, the individual bodies are biased by the second reference voltage V2 during use of the image sensor.

The current source 32 has a relatively high effective output resistance. Further, the current source 32 may include a transistor 321 and a decoupling capacitor 322 on the substrate of the third IC die 3. The transistor 321 comprises a drain D₃₂₁, a source S₃₂₁, a body B₃₂₁, and a gate G₃₂₁. The decoupling capacitor 322 is connected from the gate G₃₂₁ to the source S₃₂₁ and the body B₃₂₁. Further, the body B₃₂₁, the source S₃₂₁, and a terminal of the decoupling capacitor 322 are configured to receive the first reference voltage V1, the second reference voltage V2, or the third reference voltage V3 depending on embodiment of the image sensor. As above, the decoupling capacitor 322 stabilizes the V_{GS}.

With reference to FIG. 3B, a circuit diagram 300B of some embodiments of the image sensors of FIG. 2B is provided in which the ADC 31 and the current source 32 comprise individual transistors. As in FIG. 3A, the ADC 31 comprises the plurality of transistors 311 and the current source 32 comprises the transistor 321, as well as the decoupling capacitor 322.

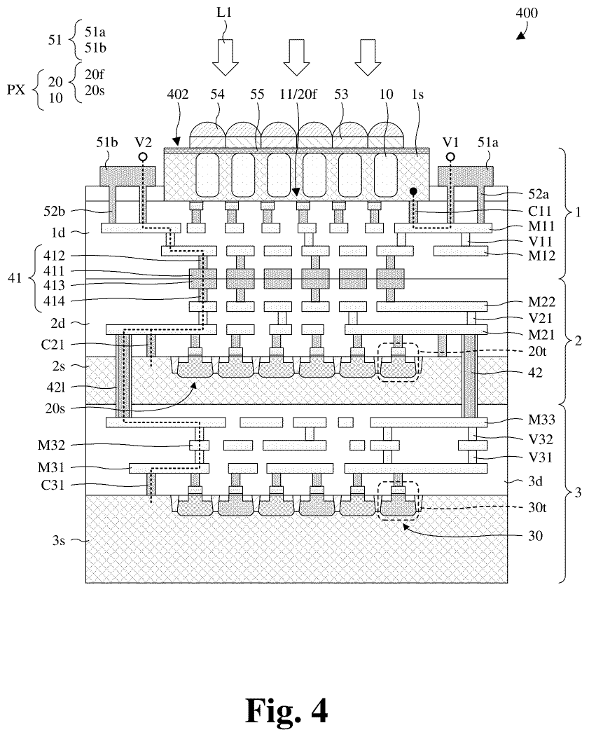

With reference to FIG. 4, a cross-sectional view 400 of some embodiments of the image sensor is provided in which the image sensor comprises a pixel array 402. The pixel array 402 comprises a plurality of pixels PX, each being as in any one or combination of FIGS. 1, 2A-2C, 3A, and 3B. The first, second, and third IC dies 1-3 are vertically stacked with the second IC die 2 being between the first and third IC dies 1, 3. Further, the first IC die 1 comprises a semiconductor substrate 1s that is sensitive to light L1, whereas the second IC die 2 comprises a semiconductor substrate 2s that is insensitive to the light L1 and the third IC die 3 comprises a semiconductor substate 3s that is insensitive to the light L1.

The first interconnect structure 41 is between the first and second IC dies 1, 2 and corresponds to a bond structure. The bond structure comprises both a dielectric-to-dielectric bond and a metal-to-metal bond, whereby the bond structure may also be referred to as a hybrid bond structure. The bond structure includes a plurality of first conductive bond layers 411 and a plurality of first conductive bond vias 412 in a dielectric structure 1d of the first IC die 1 and further includes a plurality of second conductive bond layers 413 and a plurality of second conductive bond vias 414 in a dielectric structure 2d of the second IC die 2.

The plurality of first conductive bond layers 411 are connected to the plurality of second conductive bond layers 413. The plurality of first conductive bond layers 411 and the plurality of second conductive bond layers 413 may be bonded by metal-to-metal bonding, whereas surrounding dielectric layers 1d and 2d may be bonded by dielectric-to-dielectric bonding. Some of the plurality of first conductive bond layers 411 may be connected to the plurality of first conductive bond vias 412 while a remainder of the plurality of first conductive bond layers 411 (e.g., dummy conductive bond layers) may not be. Further, some of the plurality of second conductive bond layers 413 may be connected to the plurality of second conductive bond vias 414 while a remainder of the plurality of second conductive bond layers 413 (e.g., dummy conductive bond layer) may not be.

The first IC die 1 includes a plurality of conductive wire levels M11, M12 and one or more conductive via levels V11 in the dielectric structure 1d of the first IC die 1. Although FIG. 4 shows two conductive wire levels and one conductive via level, the first IC die 1 may include more conductive wire levels and/or more conductive via levels. Conductive wire level M11 is connected to conductive wire level M12 by via level V11, and conductive wire level M12 is connected to the first conductive bond vias 412. The first IC die 1 further includes a plurality of conductive contacts C11 in the dielectric structure 1d.

The plurality of conductive contacts C11 connect conductive wire level M11 to a bulk of the semiconductor substrate 1s of the first IC die 1. Further, the plurality of conductive contacts C11 connect conductive wire level M11 to a plurality of transfer transistors 11 (more generally, first pixel-circuit portions). The plurality of transfer transistors 11 are partially shown and are associated with a plurality of pinned photodiodes 10 in the semiconductor substrate 1s of the first IC die 1. In some embodiments, there is a one-to-one correspondence between the plurality of transfer transistors 11 and the plurality of pinned photodiodes 10.

The second IC die 2 includes a plurality of conductive wire levels M21, M22 and one or more conductive via levels V21 in the dielectric structure 2d of the second IC die 2. Although FIG. 4 shows two conductive wire levels and one conductive via level, the second IC die 2 may include more conductive wire levels and/or more conductive via levels. Conductive wire level M21 is connected to conductive wire level M22 by via level V21, and conductive wire level M22 is connected to the second conductive bond vias 414. The second IC die 2 further includes a plurality of conductive contacts C21 in the dielectric structure 2d.

The plurality of conductive contacts C21 connect conductive wire level M21 to a bulk of the semiconductor substrate 2s of the second IC die 2. Further, the plurality of conductive contacts C21 connect conductive wire level M21 to a plurality of second pixel-circuit portions 20s. In some embodiments, there is a one-to-one or one-to-many correspondence between the second pixel-circuit portions 20s and the plurality of pinned photodiodes 10. The second pixel-circuit portions 20s comprise a plurality of transistors 20t, which correspond to the reset transistors 21, the source-follower transistors 22, and the row-select transistors 23 previously discussed. The plurality of transistors 20t may, for example, each be connected to conductive wire level M21 by the plurality of conductive contacts C21.

The plurality of pinned photodiodes 10, the plurality of first pixel-circuit portions 20f (e.g., the plurality of transfer transistors 11), and the plurality of second pixel-circuit portions 20s are interconnected by the wire and via levels (e.g., conductive wire level M21, via level V11, etc.) and the first interconnect structure 41 to form the pixel array 402. Each pixel PX includes a pinned photodiode 10, a first pixel-circuit portion 20f, and a second pixel-circuit portion 20s and may, for example, be as in any one or combination of FIGS. 1, 2A-2C, 3A, and 3B.

The second interconnect structure 42 corresponds to a plurality of conductive through vias. The plurality of conductive through vias extend through the semiconductor substrate 2s of the second IC die 2 and are separated from the semiconductor substrate 2s by dielectric liners 421. The conductive through vias may be copper, gold, aluminum, or the like.

The third IC die 3 includes a plurality of conductive wire levels M31, M32, M33 and a plurality of conductive via levels V31, V32 in the dielectric structure 3d of the third IC die 3. Although FIG. 4 shows three conductive wire levels and two conductive via levels, the third IC die 3 may include more conductive wire levels and/or more conductive via levels. Conductive wire level M31 is connected to conductive wire level M32 by via level V31, conductive wire level M32 is connected to conductive wire level M33 by via level V32, and conductive wire level M33 is connected to the plurality of pixel circuits 20 by the second interconnect structure 42. The third IC die 3 further includes a plurality of conductive contacts C31.

The plurality of conductive contacts C31 are in the dielectric structure 3d of the third IC die 3 and connect conductive wire level M31 to a bulk of the semiconductor substrate 3s of the third IC die 3. Further, the plurality of conductive contacts C31 connect conductive wire level M31 to an ASIC 30. The ASIC 30 comprises individual transistors 30t. The individual transistors 30t form the ADC 31 and/or the current source 32 previously discussed and may each be connected to conductive wire level M31 by the plurality of conductive contacts C31.

The first IC die 1 includes a plurality of conductive pads 51, including a first conductive pad 51a and a second conductive pad 51b, at a top of the first IC die 1, laterally adjacent to the semiconductor substrate 1s of the first IC die 1. The first IC die 1 includes one or more conductive pad vias 52a connecting the first conductive pad 51a with conductive wire level M11 and further includes one or more conductive pad vias 52b connecting the second conductive pad 51b with conductive wire level M11. The plurality of conductive pads 51 may, for example, be or comprise aluminum copper, copper, some other suitable conductive material, or a combination of the foregoing. Further, the plurality of conductive pads 51 may be connected to wire bonds (not shown) which may electrically connect a power source.

As previously discussed, the pinned photodiodes 10 and the transfer transistors 11 are configured to receive the first reference voltage V1. In FIG. 4, the image sensor is configured to receive the first reference voltage V1 at the first conductive pad 51a. Conductive features (e.g., wires, vias, contacts, etc.) of the first IC die 1 pass the first reference voltage V1 from the first conductive pad 51a to the semiconductor substrate 1s of the first IC die 1. Further, the semiconductor substrate 1s forms one or more conductive paths to pass the first reference voltage V1 to the pinned photodiodes 10 (e.g., anodes A₁₀ of the pinned photodiodes 10) and the transfer transistors 11 (e.g., bodies B₁₁ of transfer transistors 11).

Also, as previously discussed, the second pixel-circuit portions 20s and the ASIC 30 are configured to receive the second reference voltage V2. In FIG. 4, the image sensor is configured to receive the second reference voltage V2 at the second conductive pad 51b. Conductive features (e.g., wires, vias, contacts, interconnect structures, etc.) in the first, second, and third IC dies 1-3 pass the second reference voltage V2 from the second conductive pad 51bto the semiconductor substrate 2s of the second IC die 2 and to the semiconductor substrate 3s of the third IC die 2. The semiconductor substrate 2s of the second IC die 2 forms one or more conductive paths to pass the second reference voltage V2 to the transistors 20t of the second pixel-circuit portions 20s (e.g., bodies of the transistors 20t). Similarly, the semiconductor substrate 3s of the third IC die 2 forms one or more conductive paths to pass the second reference voltage V2 to the transistors 30t of the ASIC 30 (e.g., bodies of the transistors 30t).

Because the second and third IC dies 2, 3 have a common reference or ground level, the noise induced by variations of the ground level can be reduced and thus the noise at the ASIC 30 can be improved. For example, noise at an ADC 31 of the ASIC 30 (see, e.g., FIG. 1) may be reduced and SNR of the ADC 31 may be improved.

With continued reference to FIG. 4, the first IC die 1 may include a plurality of color filters 53, a plurality of microlenses 54, and an anti-reflection layer 55. The microlenses 54 are respectively on the color filters 53 and are aligned with the pinned photodiodes 10 and the color filters 53. Further, the microlenses 54 have a curved (e.g., convex) surface that focuses the light L1 respectively on the pinned photodiodes 10.

The color filters 53 are on the anti-reflection layer 55, which is between the color filters 53 and the semiconductor substrate 1s of the first IC die 1. The anti-reflection layer 55 is configured to minimize reflection of incident light and allows more light to reach the pinned photodiodes 10. In some embodiments, the anti-reflection layer 55 may be or comprise, for example, oxide, nitride, high-k dielectric material, or the like. The high-k dielectric material may, for example, be or comprise aluminum oxide (AlO), tantalum oxide (TaO), hafnium oxide (HfO), hafnium silicon oxide (HfSiO), hafnium aluminum oxide (HfAlO), or hafnium tantalum oxide (HMO), or a combination thereof.

During back-side illumination (BSI) of the image sensor, the light L1 is incident on the back of the first IC die 1 and passes, in sequence, through the microlenses 54, the color filters 53, and the anti-reflection layer 55. The light L1 then passes into the semiconductor substrate 1s of the first IC die 1 to reach the pinned photodiodes 10. In alternative embodiments, the first IC die 1 is vertically flipped while the second and third IC dies 2, 3, remain as is. In such embodiments, the back of the first IC die 1 is bonded to the second IC die 2 and the first IC die 1 receives the light L1 at a front of the first IC die 1 for front-side illumination (FSI).

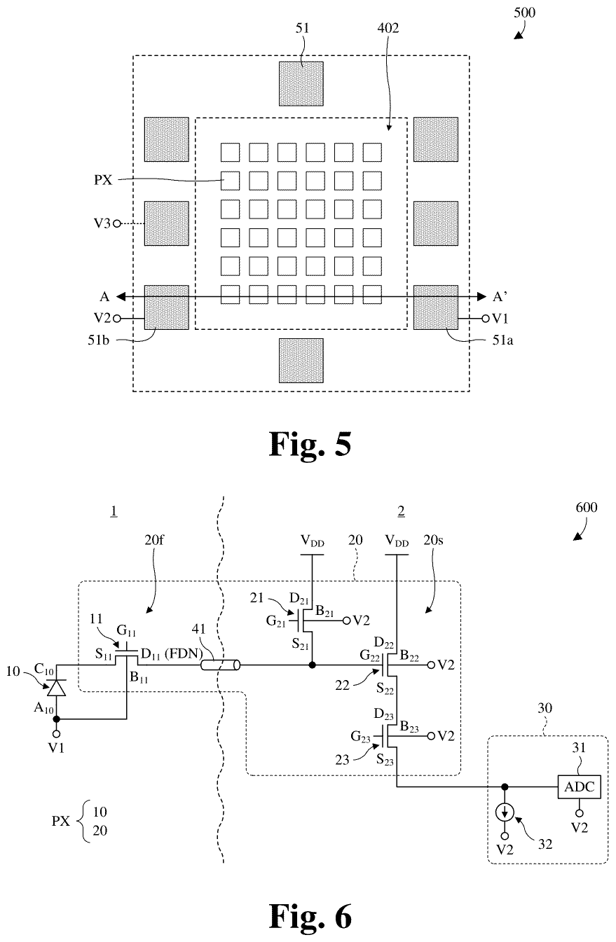

With reference to FIG. 5, a plan view 500 of some embodiments of the image sensor of FIG. 4 is provided. The cross-sectional view 400 of FIG. 4 may, for example, be taken along line A-A′ in FIG. 4. The image sensor comprises the pixel array 402, which comprises a plurality of pixels PX in a plurality of rows and a plurality of columns. Further, each pixel PX is configured as in any one or combination of FIGS. 1, 2A-2C, 3A, and 3B.

A plurality of conductive pads 51 are spaced in a ring-shaped path around the pixel array 402. The plurality of conductive pads 51 include the first conductive pad 51a, the second conductive pad 51b, and a third conductive pad 51c. The first and second conductive pads 51a, 51b are configured to respectively receive the first reference voltage V1 and the second reference voltage V2. As above, pinned photodiodes 10 of the pixels PX and transfer transistors 11 of the pixels PX are configured to receive the first reference voltage V1 from the first conductive pad 51a, whereas the pixel circuits 20 of the pixels PX are configured to receive the second reference voltage V2 from the second conductive pad 51b.

In some embodiments, anodes of the pinned photodiodes 10 and bodies of the transfer transistors 11 are electrically shorted to the first conductive pad 51a by conductive features in the first IC die 1. In some embodiments, bodies of the transistors 20t of the second pixel-circuit portions 20s and bodies of the transistors 30t forming the ASIC 30 are electrically shorted to the second conductive pad 51b by conductive features in the first, second, and third IC dies 1-3.

In some embodiments, depending upon the configuration of the pixels PX in FIGS. 4 and 5, the third conductive pad 51c is configured to receive the third reference voltage V3. Further, the current source 32 of the ASIC 30 (see, e.g., FIG. 2C) is configured to receive the third reference voltage V3 from the third conductive pad 51c. In some embodiments, a transistor body of the current source 32 is electrically shorted to the third conductive pad 51c by conductive features in the first, second, and third IC dies 1-3.

With reference to FIG. 6, a circuit diagram 600 of some embodiments of an image sensor that spans two IC dies, according to aspects of the present disclosure, is provided. The image sensor is similar to the image sensor of FIG. 1 and includes the first IC die 1 and the second IC die 2 as in FIG. 1. However, in contrast with the image sensor of FIG. 1, the third IC die 3 is omitted and the ASIC 30 is in the second IC die 2.

The pixel circuit 20 is in the second IC die 2 and is configured as described with regard to FIG. 1. Individual transistors of the second pixel-circuit portion 20s have bodies configured to receive the second reference voltage V2. Further, the ASIC 30 is in the second IC die 2 and is configured as described with regard to FIG. 1. The ADC 31 of the ASIC 30 and the current source 32 of the ASIC 30 are configured to receive the second reference voltage V2. Because the second pixel-circuit portion 20s and the ASIC 30 have the same reference voltage, variations in reference voltage are the same in the second pixel-circuit portion 20s and the ASIC 30. As a result, noise is reduced and the SNR of the ADC 31 is not negatively impacted.

The pinned photodiode 10 and the transfer transistor 11 are in the first IC die 1, and the transfer transistor 11 is electrically coupled to the pixel circuit 20 through the first interconnect structure 41. Further, the pinned photodiode 10 and the transfer transistor 11 are configured to receive the first reference voltage V1, which is independent of the second reference voltage V2. As above, the first reference voltage V1 may be more negative than the second reference voltage V2 to effectively increase supply voltage at the first IC die 1 by a magnitude of the potential difference between the first and second reference voltages V1, V2. This increases the FWC of the pinned photodiode 10 and allows complete charge transfer of photon-induced carriers out of the pinned photodiode 10.

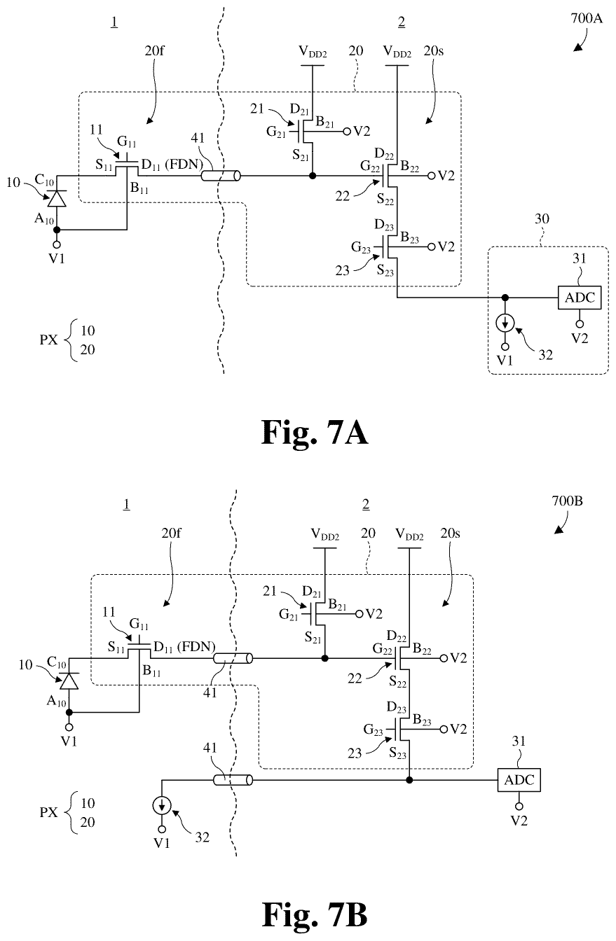

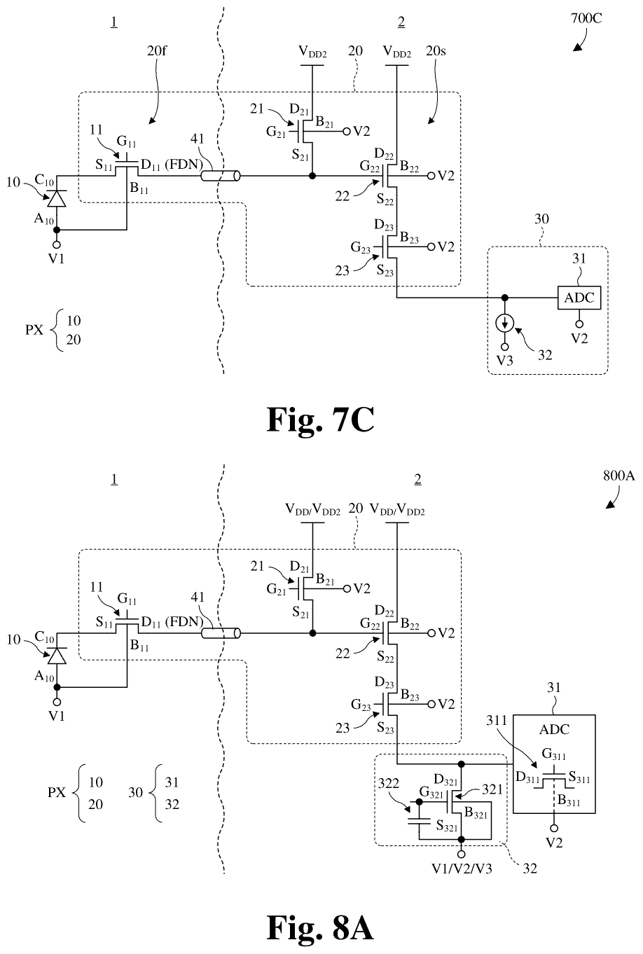

With reference to FIG. 7A, a circuit diagram 700A of some alternative embodiments of the image sensor of FIG. 6 is provided in which the pixel circuit 20 is supplied with a supply voltage V_{DD2} rather than supply voltage V_{DD}. Further, supply voltage V_{DD2} is less than supply voltage V_{DD}. As a result, the output swing range of the source-follower transistor 22 (or the input swing range of the ADC 31) may be narrower. In order to regain this loss in range, the current source 32 may be configured to receive the first reference voltage V1.

By applying the first reference voltage V1 to the current source 32, the voltage from the drain D₂₂ of the source-follower transistor 22 to the second terminal of the current source 32 is effectively increased by a magnitude of the potential difference between the first and second reference voltages V1, V2. This, in turn, increases the output swing range of the source-follower transistor 22 and the input swing range of the ADC 31.

The current source 32 may have a relatively high effective output resistance. Further, the current source 32 may include a transistor and a decoupling capacitor connected from the gate of the transistor to the source of the transistor to stabilize the V_{GS}. The relatively high effective output resistance and the stabilization of V_{GS} may provide a constant biasing current and may minimize the noise induced by the variations of the reference voltages.

With reference to FIG. 7B, a circuit diagram 700B of some alternative embodiments of the image sensor of FIG. 7A is provided in which the current source 32 has been moved to the first IC die 1. The current source 32 may be connected to the source-follower transistor 1 through the first interconnect structure 41. The current source 32 may provide a constant biasing current for the source-follower transistor 22 and is biased with the first reference voltage V1 (same as the pinned photodiode 10).

The current source 32 may be modified to improve the noise thereof. For example, special processes for manufacturing the current source 32 may be applied. The current source 32 is in a substrate of the first IC die 1 independent of the substrate of the third IC die 3. The third IC die 3, including the ADC 31, may be manufactured with standard processes, which are mostly fixed in a semiconductor manufacturing fab. The processes for manufacturing the first IC die 1 are relatively flexible as this IC die is for photodiodes. Thus, the current source 32 in the first IC die 1 can be optimized through the adjustment of the manufacturing processes without the constraints from the standard processes of the third IC die 3.

With reference to FIG. 7C, a circuit diagram 700C of some alternative embodiments of the image sensor of FIG. 7A is provided in which the current source 32 is configured to receive a third reference voltage V3 rather than the first reference voltage V1. As noted above, supply voltage V_{DD2} reduces power consumption but also reduces the output swing range of the source-follower transistor 22 (or the input swing range of the ADC 31).

In order to at least partially regain the output swing range of the source-follower transistor 22 (or the input swing range of the ADC 31), the current source 32 can be configured to receive a third reference voltage V3 that is less than the second reference voltage V2. Further, in some embodiments, the third reference voltage V3 is higher than the first reference voltage V1. Because the third reference voltage V3 is higher, the DC biasing for the inputs of the ADC 31 can be higher than they would otherwise be if the current source 32 was biased with the first reference voltage V1. This allows the DC biasing for the input of the ADC 31 to be more compatible with the designed input range of the ADC 31.

In some embodiments, the third reference voltage V3 and the second reference voltage V2 are derived from the same voltage source. Although these reference voltages may be derived from the same voltage source, a voltage divider may introduce variations (or noises), such that the third reference voltage V3 may not track the second reference voltage V2. In order to prevent the variations from affecting the biasing current, the current source 32 may have a relatively high effective output resistance. Further, the current source 32 may include a transistor and a decoupling capacitor connected from the gate of the transistor to the source of the transistor to stabilize the V_{GS}.

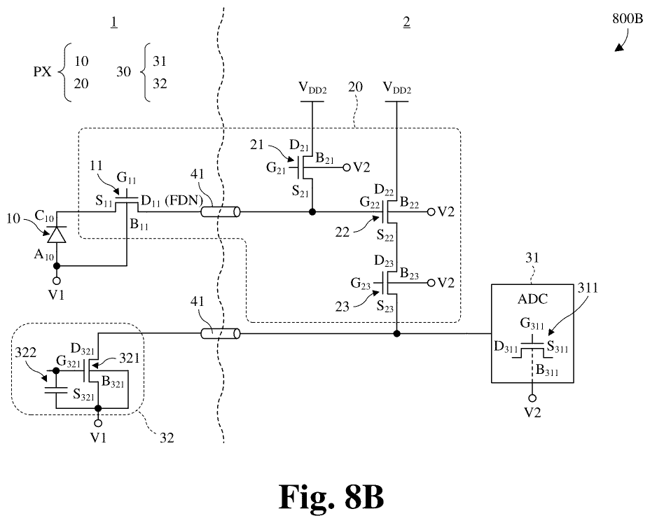

With reference to FIG. 8A, a circuit diagram 800A of some embodiments of the image sensors of FIGS. 6, 7A, or 7C is provided in which the ADC 31 and the current source 32 comprise individual transistors. Further, depending on embodiment of the image sensor, the pixel circuit 20 receives supply voltage V_{DD} or supply voltage V_{DD2}.

The ADC 31 comprises a plurality of transistors 311 that are interconnected to implement functions of the ADC 31 and that have individual bodies B₃₁₁ configured to receive the second reference voltage V2. The current source 32 comprises a transistor 321 and a decoupling capacitor 322. The decoupling capacitor 322 is connected from the gate G₃₂₁ of the transistor 321 to the source S₃₂₁ of the transistor 321 and the body B₃₂₁ of the transistor 321. Further, the body B₃₂₁, the source S₃₂₁, and a terminal of the decoupling capacitor 322 are configured to receive the first reference voltage V1, the second reference voltage V2, or the third reference voltage V3 depending on embodiment of the image sensor.

With reference to FIG. 8B, a circuit diagram 800B of some embodiments of the image sensors of FIG. 7B is provided in which the ADC 31 and the current source 32 comprise individual transistors. As in FIG. 8A, the ADC 31 comprises the plurality of transistors 311 and the current source 32 comprises the transistor 321, as well as the decoupling capacitor 322.

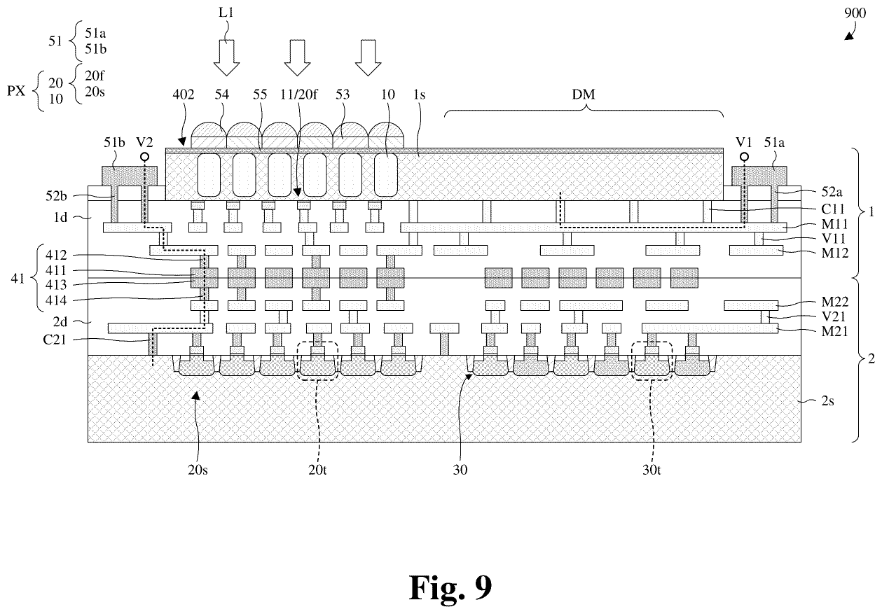

With reference to FIG. 9, a cross-sectional view 900 of some embodiments of the image sensor is provided in which the image sensor comprises a pixel array 402. The pixel array 402 comprises a plurality of pixels PX, each being as in any one of combination of FIGS. 6, 7A-7C, 8A, and 8B. The image sensor is as in FIG. 4, except that the third IC die 3 has been omitted. Further, the ASIC 30 has been moved to the second IC die 2, laterally offset from the plurality of pixel circuits 20. As such, the ASIC 30 and the plurality of pixel circuits 20 share the semiconductor substrate 2s of the second IC die 2. This may reduce the cost to manufacture the image sensor and may improve yields, as compared to the image sensor of FIG. 4.

As previously discussed, the pinned photodiodes 10 and the transfer transistors 11 (more generally, the first pixel-circuit portions 20f) are configured to receive the first reference voltage V1. For example, as illustrated in the cross-sectional view 900, the image sensor is configured to receive the first reference voltage V1 at the first conductive pad 51a. Conductive features (e.g., wires, vias, contacts, etc.) of the first IC die 1 pass the first reference voltage V1 from the first conductive pad 51a to the semiconductor substrate 1s of the first IC die 1. Further, the semiconductor substrate 1s forms one or more conductive paths to pass the first reference voltage V1 to the pinned photodiodes 10 (e.g., anodes A₁₀ of the pinned photodiodes 10) and the transfer transistors 11 (e.g., bodies B₁₁ of transfer transistors 11).

Also, as previously discussed, the second pixel-circuit portions 20f and the ASIC 30 are configured to receive the second reference voltage V2. For example, as illustrated in the cross-sectional view 900, the image sensor is configured to receive the second reference voltage V2 at the second conductive pad 51b. Conductive features (e.g., wires, vias, contacts, interconnect structures, etc.) in the first and second IC dies 1, 2 pass the second reference voltage V2 from the second conductive pad 51b to the semiconductor substrate 2s of the second IC die 2. The semiconductor substrate 2s of the second IC die 2 forms one or more conductive paths to pass the second reference voltage V2 to bodies of the transistors 20t of the second pixel-circuit portions 20f and bodies of the transistors 30t of the ASIC 30.

Because the second pixel-circuit portions 20f and the ASIC 30 have a common reference or ground level, the noise induced by variations of the ground level can be reduced and thus the noise at the ASIC 30 can be improved. For example, noise at an ADC 31 of the ASIC 30 (see, e.g., FIG. 6) may be reduced and SNR of the ADC 31 may be improved.

With continued reference to FIG. 9, the pixel circuits 20 and the pinned photodiodes 10 may overlap vertically. Further, the ASIC 30 may be free from vertical overlap with the pinned photodiodes 10. Instead, the ASIC 30 may vertically overlap with a dummy region DM of the first IC die 1 that is not used for the conversion of light (e.g., photon) to carriers (e.g. electron). The dummy region DM may include dummy conductive patterns to avoid a large difference in pattern density between the pinned photodiodes 10 and the dummy region DM. Further, in some embodiments, the dummy region DM may include a capacitor, resistor, or transistor that electrically connected to the pinned photodiodes 10.

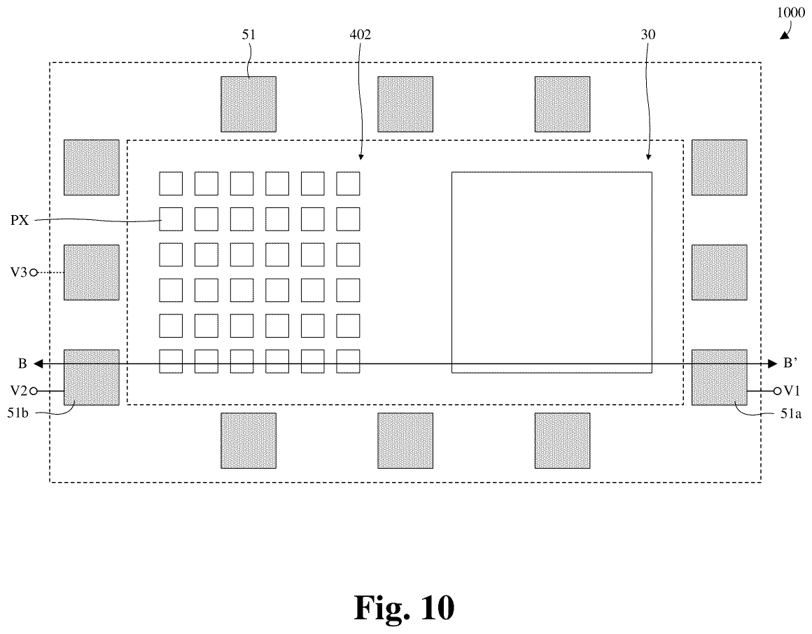

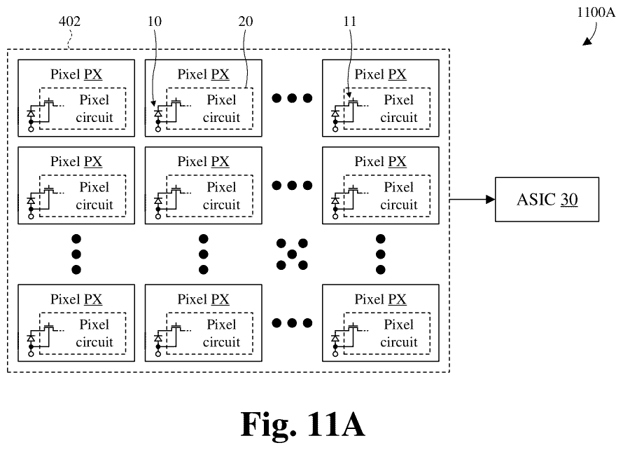

With reference to FIG. 10, a plan view 1000 of some embodiments of the image sensor of FIG. 9 is provided. The cross-sectional view 900 of FIG. 9 may, for example, be taken along line B-B′ in FIG. 10. The image sensor comprises a pixel array 402 and an ASIC 30 that laterally border each other. The pixel array 402 comprises a plurality of pixels PX in a plurality rows and a plurality of columns. Further, each pixel PX is configured as in any one or combination of FIGS. 6, 7A-7C, 8A, and 8B.

A plurality of conductive pads 51 are spaced in a ring-shaped path around the pixel array 402 and the ASIC 30 and include the first conductive pad 51a, the second conductive pad 51b, and a third conductive pad 51c. The first and second conductive pads 51a, 51b are configured to respectively receive the first reference voltage V1 and the second reference voltage V2. As above, pinned photodiodes 10 of the pixels PX and transfer transistors 11 of the pixels PX are configured to receive the first reference voltage V1 from the first conductive pad 51a, whereas the ASIC 30 and the pixel circuits 20 of the pixels PX are configured to receive the second reference voltage V2 from the second conductive pad 51b.

In some embodiments, anodes of the pinned photodiodes 10 and bodies of the transfer transistors 11 are electrically shorted to the first conductive pad 51a by conductive features in the first IC die 1. Further, in some embodiments, bodies of the transistors 20t of the second pixel-circuit portions 20f and bodies of the transistors 30t of the ASIC 30 are electrically shorted to the second conductive pad 51b by conductive features in the first and second IC dies 1, 2.

In some embodiments, depending upon the configuration of the pixels PX in FIGS. 9 and 10, the third conductive pad 51c is configured to receive the third reference voltage V3. Further, the current source 32 of the ASIC 30 (see, e.g., FIG. 7C) is configured to receive the third reference voltage V3 from the third conductive pad 51c. In some embodiments, a transistor body of the current source 32 is electrically shorted to the third conductive pad 51c by conductive features in the first and second IC dies 1, 2.

As seen above, and similar to FIGS. 1, 2A-2C, 3A, 3B, 4-6, 7A-7C, 8A, 8B, 9 and 10 illustrate various different reference voltages. In some embodiments, all terminals configured to receive the first reference voltage V1 are electrically shorted together and/or electrically shorted to a first conductive pad, all terminals configured to receive the second reference voltage V2 are electrically shorted together and/or electrically shorted to a second conductive pad, and all terminals configured to receive the third reference voltage V3 are electrically shorted together and/or electrically shorted to a third conductive pad. Such electrical shorting may, for example, be by conductive wires, vias, contacts, and the like of the image sensor.

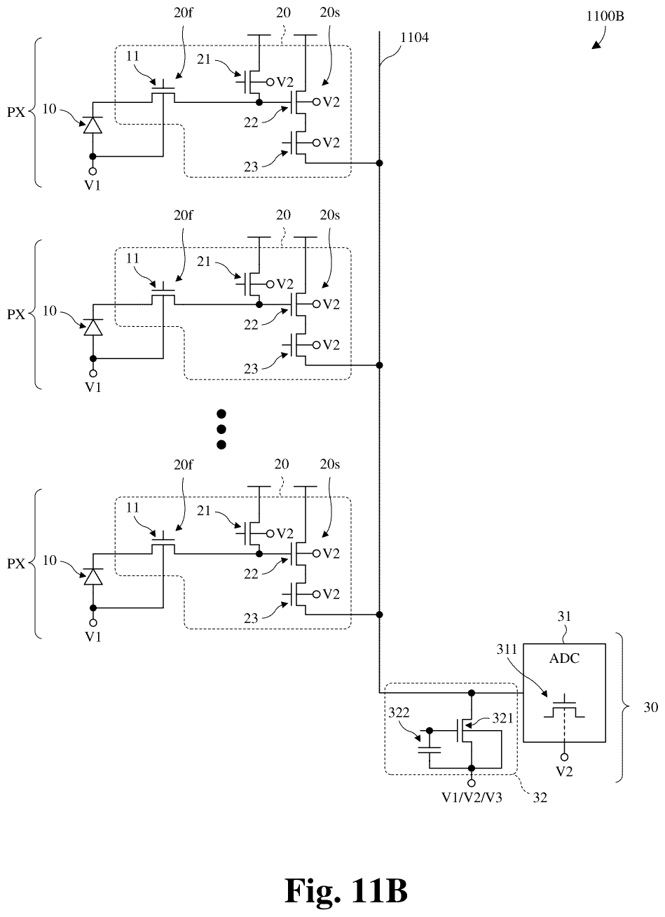

With reference to FIG. 11A, a block diagram 1100A of some embodiments of an image sensor comprising a plurality of pixels PX, each as in any one or combination of FIGS. 1, 2A-2C, 3A, 3B, 4-6, 7A-7C, 8A, 8B, 9 and 10, is provided. The plurality of pixels PX are in a plurality of rows and a plurality or columns to form a pixel array 402. For example, at least 3 rows and at least 3 columns are illustrated. However, there may be more or less rows and/or more or less columns in alternative embodiments.

The plurality of pixels PX comprise individual pinned photodiodes 10 and individual pixel circuits 20, which include first pixel-circuit portions 20f (e.g., transfer transistors 11) and second pixel-circuit portions 20s. Further, the plurality of pixels PX share the ASIC 30 and are each electrically coupled to the ASIC 30. Therefore, there may be only one ASIC 30 in at least some embodiments. As above, the pinned photodiodes 10 and the transfer transistors 11 are in the first IC die 1 with the first reference voltage V1, and the second pixel-circuit portions are in the second IC die 2 with the second reference voltage V2. Further, the ASIC 30 is at least partially in a second or third IC die 2, 3 with the second reference voltage V2.

With reference to FIG. 11B, a circuit diagram 1100B of a column in the pixel array 402 of FIG. 11A is provided. Pixels PX in the column are individually connected to a conductive line 1104. Said connection may, for example, be via sources of row-select transistors 23 in the individual pixels PX. The conductive line 1104 extends to the ASIC 30 and electrically couples with an ADC 31 and a current source 32, which are as in any one or combination of FIGS. 1, 2A-2C, 3A, 3B, 4-6, 7A-7C, 9A, 9B, and 10.

In some embodiments, the column illustrated by FIG. 11B is representative of each individual column in the pixel array 402 of FIG. 11A. Further, in some embodiments, the conductive line 1104, the ADC 31, and the current source 32 repeat for each individual column of the pixel array 402, such that the ASIC 30 may include an ADC and a current source for each individual column of the pixel array 402.

In view of the foregoing, at least some embodiments of the present disclosure relate to an image sensor including a first group of devices with at least one pinned photodiode and at least one transfer transistor, a second group of devices with at least one pixel circuit, and a third group of devices with an electronic device. The electronic device may, for example, correspond to the ADC 31 or some other suitable electronic device.

The first group of devices is connected to the second group of devices through a first interconnect structure. The pixel circuits of the second group of devices control at least one pinned photodiode and at least one transfer transistor of the first group of devices. The electronic device processes signals from the second group of devices. The first group of devices is biased with a negative reference voltage. The second group of devices and the electronic device are biased with the same reference voltage, providing the second group of devices and the electronic device with the same ground level. Hence, variations in ground will not induce noise and, at least where the electronic device is an ADC, the SNR of the ADC is improved

Further, the negative reference voltage applied to the first group of devices is more negative than the reference voltage that is applied to the second group of devices. In the reset mode of the image sensor, the at least one pinned photodiode can be sufficiently reset by the at least one pixel circuits and, in the charge transfer mode of the image sensor, photon-induced carriers in the at least one pinned photodiode can be completely transferred to at least one FDN.

While the present disclosure has thus far focused on image sensors, it is to be appreciated that the aforementioned concepts are applicable to other device types. For example, circuit components can be shifted, and/or additional voltages can be added to other device types, to reduce noise and/or enhance performance. Such other device types include, for example, Microelectromechanical Systems (MEMS) microphones, biosensors, three-dimensional (3D) memory, 3D fabric, photonics, and so on.

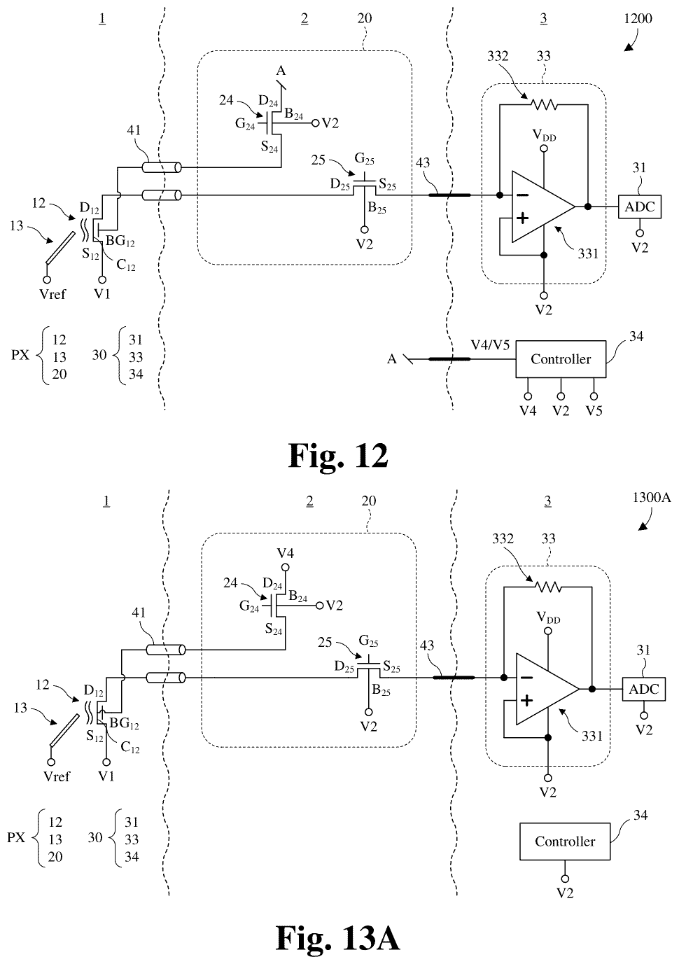

With reference to FIG. 12, a circuit diagram 1200 of some embodiments of a biosensor that spans three IC dies, according to aspects of the present disclosure, is provided. The biosensor is similar to the image sensor of FIG. 1 in that it includes the first IC die 1, the second IC die 2, and the third IC die 3. However, as seen below, there are a number of differences to account for the change in sensor type.

The first and second IC dies 1, 2 are electrically coupled and bonded together by the first interconnect structure 41, whereas the second and third IC die 2, 3 are electrically coupled together by an internal wire bond structure 43. Further, the pixel PX spans the first and second IC dies 1, 2 and comprises a bio field-effect transistor (BioFET) 12, a reference electrode 13, and a pixel circuit 20. The BioFET 12 and the reference electrode 13 are in the first IC die 1, and the pixel circuit 20 is entirely within the second IC die 2. The BioFET 12 may, for example, be an ion-sensitive field-effect transistor (ISFET) or some other suitable type of BioFET.

The BioFET 12 is configured to sense a variety of bioentities present in a fluid proximate a channel C₁₂ of the BioFET 12. Such bioentities may, for example, include molecules like DNA, proteins, cells, and so on. In some embodiments, the sensing mechanism relies on detecting changes in ion concentration near the channel C₁₂. When a bioentity binds to a specialized bio-sensing film at the channel C₁₂, it triggers the release of ions into the fluid. For example, when a DNA segment binds, it may release hydrogen ions (H+), altering the local pH. The change in ion concentration impacts the conductivity of the channel C₁₂, thereby providing a measurable output signal that is proportional to the amount of bound bioentity.

The reference electrode 13 is configured to receive a reference voltage V_{ref} and create a stable electric field within the channel C₁₂ of the BioFET 12. As a result, the reference electrode 13 acts as a gate electrode to control channel conductivity. This enables accurate detection of subtle shifts caused by bioentities and tuning of the BioFET sensitivity.

The BioFET 12 has the channel C₁₂, a front gate formed by the reference electrode 13, and a back gate BG₁₂ electrically coupled to the pixel circuit 20. Further, the BioFET 12 has a first terminal electrically coupled to an input of the pixel circuit 20 and a second terminal configured to receive the first reference voltage V1. As seen hereafter, the first reference voltage V1 may be negative to increase a voltage across the BioFET 12 during sensing, thereby increasing sensitivity and output range of the BioFET 12. The first terminal may, for example, correspond to a drain D₁₂ of the BioFET 12, and the second terminal may, for example, correspond to a source S₁₂ of the BioFET 12, or vice versa.

The pixel circuit 20 is electrically coupled to the first terminal (e.g., output) of the BioFET 12 via the first interconnect structure 41 and is configured to facilitate readout and operation of the BioFET 12. The pixel circuit 20 comprises a plurality of pixel transistors that have individual transistor bodies (e.g., body B₂₄ and body B₂₅) electrically coupled together (e.g., via a substrate of the second IC die 2) and that are configured to receive a second reference voltage V2 greater than the first reference voltage V1. The plurality of pixel transistors include a support transistor 24 and a select transistor 25.

The support transistor 24 is configured to selectively electrically couple a back gate BG₁₂ of the BioFET 12 to a fourth voltage V4 and/or a fifth voltage V5. The fourth voltage V4 and/or a fifth voltage V5 may, for example, be received from the ASIC 30.

In some embodiments, the fourth voltage V4 is applied between sensing cycles to repel ions and/or charges that have accumulated at the BioFET 12 from previous sensing cycles. Such ions and/or charges influence the conductance of the channel C₁₂ and hence induce skew the measurements by the BioFET 12. The fourth voltage V4 may, for example, be positive if the ions and/or charge are positive and may, for example, be negative if the ions and/or charge are negative. In some embodiments, the fifth voltage V5 is applied during sensing to attract ions to the channel C₁₂ to increase sensitivity of the BioFET 12. For example, the fifth voltage V5 may be positive if the ions are negative and may be negative if the ions are positive.

In some embodiments, the fourth voltage V4 is different than the first voltage V1 and/or the second voltage V2, and/or the fifth voltage V5 is different than the first voltage V1 and/or the second voltage V2. In some embodiments, the fourth voltage V4 or the fifth voltage V5 is equal to or about equal to the first voltage V1. In some embodiments, the fourth voltage V4 is greater than the first voltage V2, greater than the second voltage V2, between the first voltage V1 and the second voltage V2, or less than the first voltage V1. Further, in some embodiments, the fourth voltage V5 is greater than the first voltage V2, greater than the second voltage V2, between the first voltage V1 and the second voltage V2, or less than the first voltage V1. In some embodiments, terminals sharing voltages in any figure herein may be electrically shorted together by conductive features of the semiconductor structure.

The select transistor 25 is configured to selectively electrically couple the first terminal (e.g., an output) of the BioFET 12 to an input of the ASIC 30. The pixel PX may, for example, be one of many pixels electrically coupled to the input of the ASIC 30, whereby the select transistor 25 allows the pixels to be readout sequentially over time using the same signal line and circuitry (e.g., amplifier, ADC, etc.) within the ASIC 30.

The ASIC 30 is in the third IC die 3 and electrically coupled to the pixel circuit 20 by the internal wire bond structure 43. The ASIC 30 may, for example, provide control over operation of the pixel PX and/or may, for example, perform analog-to-digital conversion (ADC), signal processing, and the like on an output of the pixel circuit 20. The ASIC 30 comprises an ADC 31, a transimpedance amplifier (TIA) 33, and a controller 34. The ASIC 30, the TIA 33, and the controller 34 (more generally the ASIC 30) are configured to receive the second reference voltage V2. For example, the ADC 31, the TIA 33, and the controller 34 may comprise transistors with bodies configured to receive the second reference voltage V2.

The TIA 33 is electrically coupled from an output of the pixel circuit 20 to an input of the ADC 31. The TIA 33 is configured to convert a variable current produced by the BioFET 12 during sensing into a voltage, and the ADC 31 is configured to convert the voltage into a digital signal that can undergo digital processing. The controller 34 is configured to provide control signals to the pixel PX to change the pixel between sensing and resetting. For example, the controller 34 may turn the support transistor 24 to an ON state, turn the select transistor 25 to an OFF state, and provide the fourth voltage V4 to the support transistor 24 while resetting the BioFET 12 between sensing cycles. As another example, the controller 34 may turn the support transistor 24 to an ON, turn the select transistor 25 to an ON state, and provide the fifth voltage V5 to the support transistor 24 during a sensing cycle with the BioFET 12.

In some embodiments, the BioFET 12 may be generalized as a sensor, a functional device, or the like. In some embodiments, the pixel circuit 20 may be generalized as an interface circuit for the BioFET 12. In some embodiments, the ASIC 30 may be generalized as a control and/or processing circuit for the pixel circuit 20 and/or the BioFET 12.

A reference voltage (more generally any voltage) is subject to (random) variations. Such variations may, for example, correspond to stray voltages and/or may, for example, arise from the resistance of bond wires, conductive traces, etc. in the IC dies. With different reference voltages, the variations in one reference voltage are different than, and hence don't track, the variations in the one or more other reference voltages. This non-tracking may lead to noise that negatively affects the performance (e.g., the SNR) of the ADC 31.

Because the pixel circuit 20, the ADC 31, and the TIA 33 are configured to receive the second reference voltage V2 (e.g., the same reference voltage), these circuit components have the same reference voltage. Hence, the ADC 31 has the same reference-voltage variations as the pixel circuit 20 and the TIA 33. This prevents noise induced by different reference voltages respectively at the pixel circuit 20 and the ASIC 30 and enhances the performance.

In some embodiments, the first reference voltage V1 is negative, whereas the second reference voltage V2 is ground or otherwise greater than the first reference voltage V1. As a result, the voltage across the BioFET 12 is relative to the first reference voltage V1 rather than the second reference voltage V2. This effectively increases this voltages by a magnitude of the potential difference between the first and second reference voltages V1, V2.

The affective increase in voltage at the BioFET 12 allows the supply voltage to be reduced and/or performance of the biosensor to be enhanced. For example, the reduced supply voltage reduces power consumption and may, for example, coincide with scaling down of the biosensor. As another example, the increased voltage increases the sensitivity and output range of the BioFET 12 to enhance the performance of the biosensor.

With continued reference to FIG. 12, the support transistor 24 includes a gate G₂₄, a source S₂₄, a drain D₂₄, and a body B₂₄. The body B₂₄ is configured to receive the second voltage V2, and the gate G₂₄ is configured to receive a control signal (e.g., from the ASIC 30) to selectively change the support transistor 24 between an ON state and an OFF state. The source S₂₄ is electrically coupled to the back gate BG₁₂ of the BioFET 12 and the drain D₂₄ is electrically coupled to the controller 34 of the ASIC 30. Note that the connection is broken for ease of illustrations and both terminals labeled “A” are the same.

The select transistor 25 includes a gate G₂₅, a source S₂₅, a drain D₂₅, and a body B₂₅. The body B₂₅ is configured to receive the second voltage V2, whereas the gate G₂₅ is configured to receive a control signal (e.g., from the ASIC 30) to selectively change the select transistor 25 between an ON state and an OFF state. The source S₂₅ is electrically coupled to an input of the TIA 33, and the drain D₂₄ is electrically coupled to the second terminal (e.g., output) of the BioFET 12. In some embodiments, the source S₂₅ is electrically coupled to the input of the TIA 33 via is a bus line (not shown) shared with other pixels.

In some embodiments, the support transistor 24 and the select transistor 25 are N-channel field-effect transistors. In alternative embodiments, the support transistor 24 and the select transistor 25 are P-channel field-effect transistors. In at least some of such alternative embodiments, the electrical couplings of the sources S₂₄, S₂₅ and the electrical couplings of the drains D₂₄, D₂₅ are reversed. For example, the drain D₂₄ of the support transistor 24 electrically couples to the back gate BG₁₂ of the BioFET 12 and the source S₂₄ of the support transistor 24 electrically couples to the controller 34 of the ASIC 30.

The TIA 33 includes an operational amplifier 331 and a resistor 332. The operational amplifier 331 includes a positive input terminal, a negative input terminal, an output terminal, a supply terminal, and a reference terminal. The supply terminal is configured to receive a supply voltage V_{DD}, and the reference terminal is configured to receive the second voltage V2. As noted above, the second voltage V2 may, for example, be ground. The positive input terminal is electrically coupled (e.g., shorted) to the reference terminal. The negative input terminal is electrically coupled to an output of the pixel circuit (e.g., a source S₂₅ of the select transistor 25). The output terminal is electrically coupled to an input of the ADC 31, and the resistor 332 is electrically coupled from the negative input terminal to the output terminal. In alternative embodiments, the TIA 33 may have some other suitable structure.

In some embodiments, during use of the biosensor, a sensing well of the BioFET 12 is exposed to an aqueous fluid that may contain DNA segments, as well as auxiliary components such as primers, polymerase, and deoxynucleoside triphosphates (dNTPs). A reference bias is applied to the reference electrode 13. If DNA segments are present in the fluid, thermal cycling is performed to replicate the DNA segments and increase their concentration for more reliable detection. The binding of DNA segments to a bio-sensing film at a channel of the BioFET 12 releases hydrogen ions into the fluid, increasing the pH in the fluid and altering the conductance of the channel. Therefore, the change in conductance of the channel is proportional to the concentration of DNA segments in the fluid. While this example demonstrates detection through pH variations, it is appreciated that different biological entities and detection mechanisms are amenable and can be used for various applications.

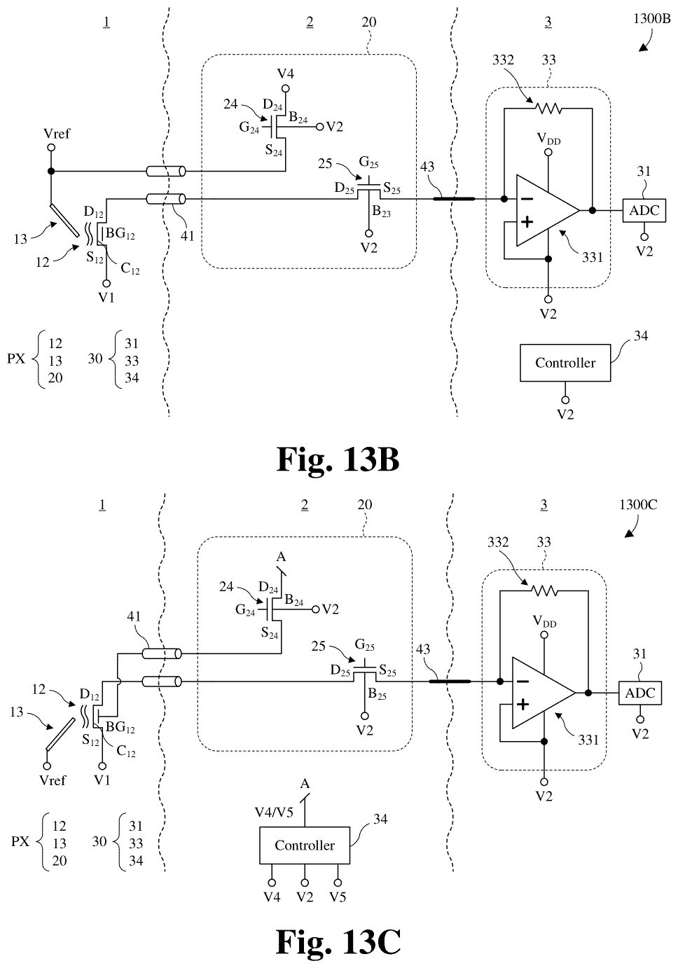

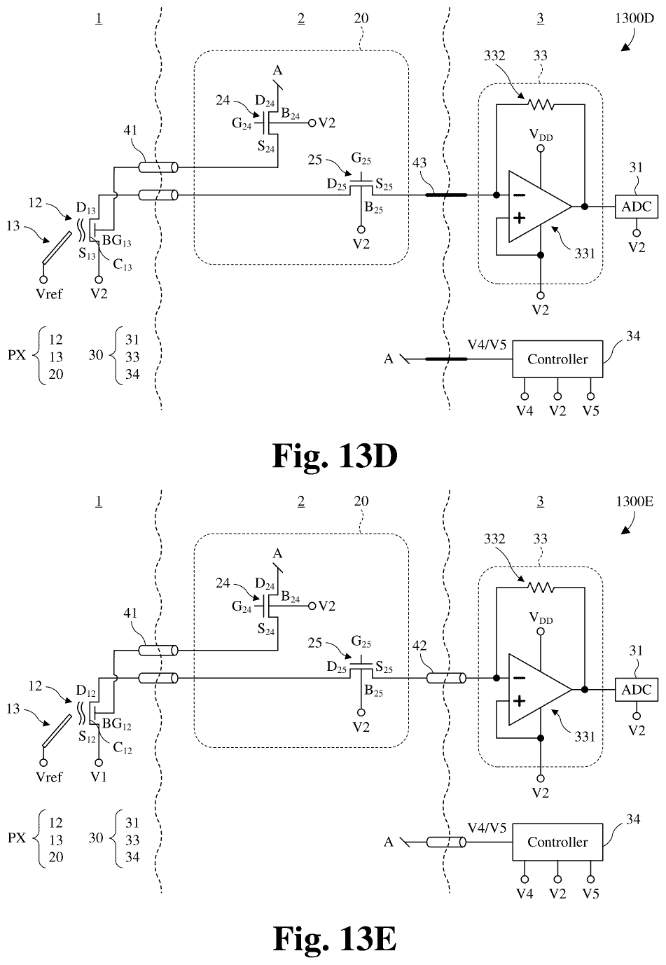

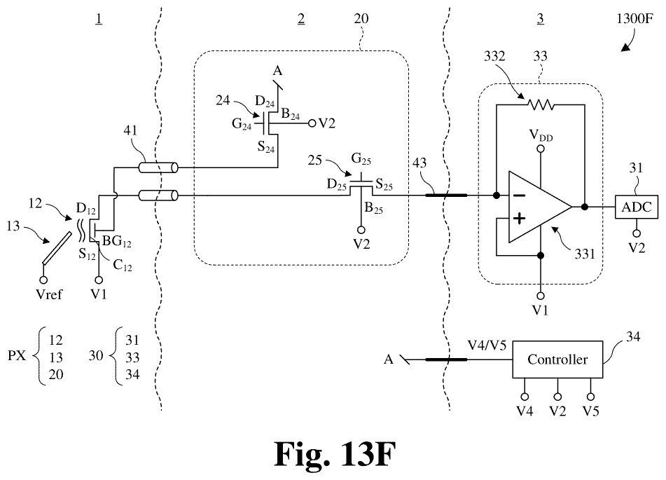

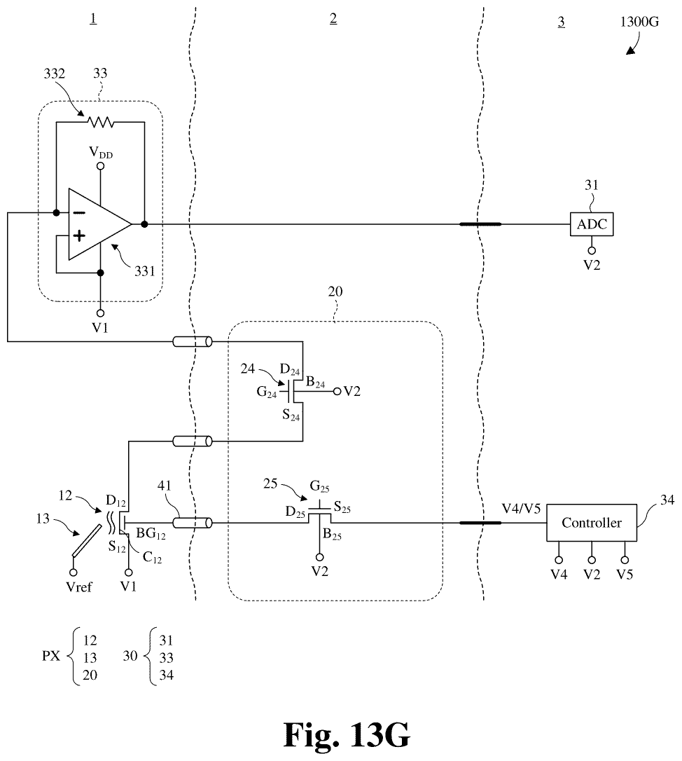

With reference to FIGS. 13A and 13B, circuit diagrams 1300A, 1300B of some alternative embodiments of the biosensor of FIG. 12 are provided. In FIG. 13A, the support transistor 24 is instead electrically coupled to the channel C₁₂ of the BioFET 12. In FIG. 13B, the support transistor 24 is instead electrically coupled to the reference electrode 13.

The support transistor 24 is configured to selectively electrically couple the channel C₁₂ or the reference electrode 13 to the fourth voltage V4 between sensing cycles to repel charge away from the channel C₁₂ of the BioFET 12. As noted above, such ions and/or charges influence the conductance of the channel C₁₂ and hence skew measurements by the BioFET 12. Further, rather than receiving the fourth voltage V4 via the controller 34, the support transistor 24 may receive the fourth voltage V4 directly. In alternative embodiments, the fourth voltage V4 is still received via the controller 34, similar to FIG. 12.

With reference to FIG. 13C, a circuit diagram 1300C of some alternative embodiments of the biosensor of FIG. 12 is provided in which the controller 34 of the ASIC 30 is instead in the second IC die 2. As a result, the ASIC 30 spans the second and third IC dies 2, 3.

With reference to FIG. 13D, a circuit diagram 1300D of some alternative embodiments of the biosensor of FIG. 12 is provided in which the BioFET 12 is configured to receive the second voltage V2, instead of the first voltage V1, at the second terminal (e.g., source S12) of the BioFET 12. The second terminal may, for example, be electrically coupled (e.g., shorted) to individual transmit bodies of the pixel circuit 20 and the ASIC 30.

With reference to FIG. 13E, a circuit diagram 1300E of some alternative embodiments of the biosensor of FIG. 12 is provided in which the second and third IC dies 2, 3 are bonded and electrically coupled together by the second interconnect structure 42 instead of by the internal wire bond structure 43. Hence, the first, second, and third IC dies 1, 2, 3 may be stacked together in a common 3D IC die or some other suitable structure.

With reference to FIG. 13F, a circuit diagram 1300F of some alternative embodiments of the biosensor of FIG. 12 is provided in which the TIA 33 is further configured to receive the first voltage V1, instead of the second voltage V2, at its reference terminal. As noted above, the first voltage V1 may, for example, be less (e.g., negative) than the second voltage V2. Hence, the voltage across the operational amplifier 331 may be larger and the output range of the TIA may be larger than it would otherwise be. This may, for example, enhance performance.

With reference to FIG. 13G, a circuit diagram 1300G of some alternative embodiments of the biosensor of FIG. 13F is provided in which the TIA 33 is in the first IC die 1. Hence, the ASIC 30 is split amongst the first and third IC dies 1, 3.

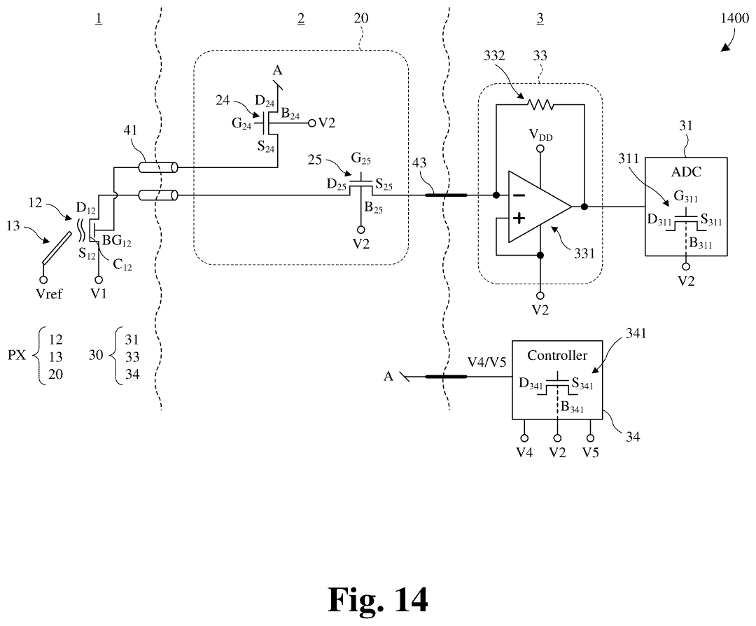

With reference to FIG. 14, a circuit diagram 1400 of some embodiments of the image sensors of FIG. 1 is provided in which the ADC 31 and the controller 34 comprise individual transistors. The ADC 31 comprises a plurality of transistors 311 (only one of which is shown) that are interconnected to implement functions of the ADC 31. The plurality of transistors 311 comprise individual drains D311, individual sources S311, individual bodies B311, and individual gates G311. The individual bodies B311 are configured to receive the second reference voltage V2 and are on the substrate of the third IC die 3. Hence, the individual bodies are biased by the second reference voltage V2 during use of the biosensor.

Similar to the ADC 31, the controller 34 comprises a plurality of transistors 341 (only one of which is shown) that are interconnected to implement functions of the controller 34. The plurality of transistors 341 comprise individual drains D₃₄₁, individual sources S₃₄₁, individual bodies B₃₄₁, and individual gates G₃₄₁. The individual bodies B₃₄₁ are configured to receive the second reference voltage V2 and are on the substrate of the third IC die 3. Hence, the individual bodies are biased by the second reference voltage V2 during use of the biosensor.

While not shown, the operational amplifier 331 of the TIA 33 may also comprise individual transistors that are interconnected to implement functions of the operational amplifier 331. These transistors may be similar to the transistors of the ADC 31 and the controller 34 and may hence have individual bodies configured to receive the second reference voltage V2.

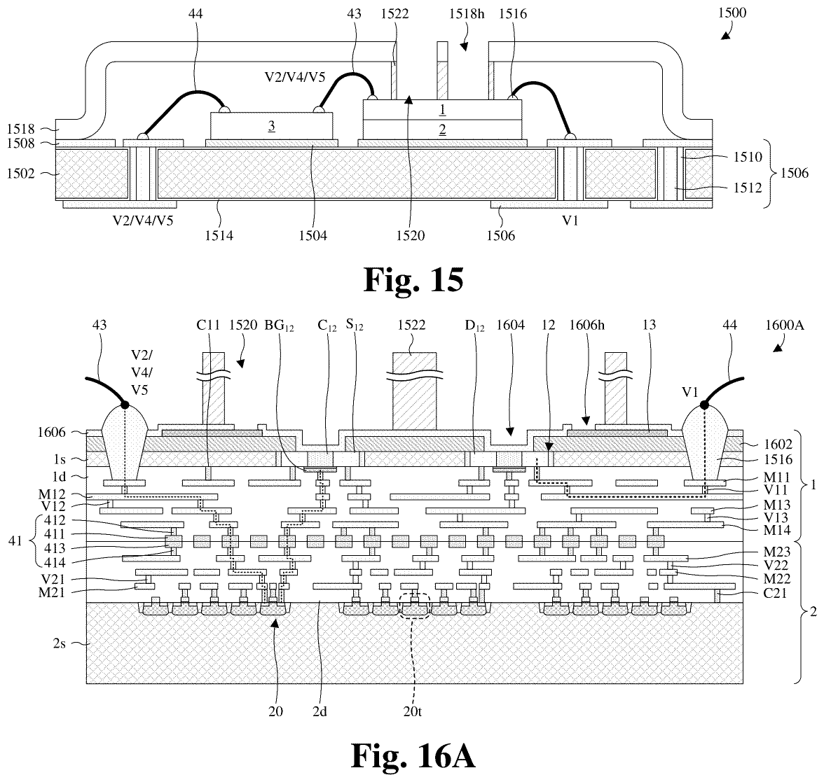

With reference to FIG. 15, a cross-sectional view 1500 of some embodiments of the biosensor of FIG. 12 is provided. The first and second IC dies 1, 2 are stacked and bonded together on a package substrate 1502. Such bonding may, for example, be via the first interconnect structure 41 of FIG. 12, which may also provide electrical coupling. The third IC die 3 is on the package substrate 1502, laterally adjacent to the first and second IC dies 1, 2. Further, the third IC die 3 is electrically coupled to the first and second IC dies 1, 2 by the internal wire bond structure 43, which extends from the third IC die 3 to the first IC die 1.

The package substrate 1502 underlies and is bonded to the second and third 2, 3 by adhesive layers 1504. The package substrate 1502 may, for example, correspond to a printed circuit board (PCB) 1506 or some other suitable type of substrate. In alternative embodiments, the package substrate 1502 may, for example, be or comprise silicon and/or may, for example, correspond to a silicon interposer structure.

A plurality of package pads 1508 are on a top of the package substrate 1502 and a bottom of the package substrate 1502. Further, a plurality of package vias 1510 extend through the package substrate 1502, between package pads on a top of the package substrate 1502 and package pads on a bottom of the package substrate 1502. The package pads on the package substrate 1502 may, for example, be configured to receive voltages for powering and/or controlling the biosensor. Such voltages may, for example, include any one or combination of the voltages V1, V2, V4, V5, and/or some other suitable voltages.

A plurality of external wire bond structures 44 extend from package pads on the top of the package substrate 1502 respectively to the third IC die 3 and the first IC die 1 to provide external connectivity to these dies. The plurality of external wire bond structures 44 may, for example, interface with package pads and/or the IC dies via bump structures 1516. The bump structures 1516 may, for example, be solder bumps or some other suitable type of structure.

In some embodiments, the plurality of package vias 1510 surround corresponding dielectric cores 1512 extending through the package substrate 1502. Further, in some embodiments, the plurality of package vias 1510 are separated from the package substrate 1502 by a dielectric layer 1514. The dielectric layer 1514 may, for example, be localized to the plurality of package vias 1510 or may surround the package substrate 1502 as shown.

A lid 1518 overlies the package substrate 1502 and the first, second, and third IC dies 1, 2, 3. Further, the lid 1518 surrounds the first, second, and third IC dies 1, 2, 3. The lid 1518 has one or more holes 1518h, which overlie the first IC die 1 and are aligned with fluidic channels 1520 formed by a channel structure 1522. The one or more holes 1518h are configured to receive fluid with entities for detection by the BioFETs of the first IC die 1, and the fluidic channels 1520 are configured to carry the fluid to the BioFETs.

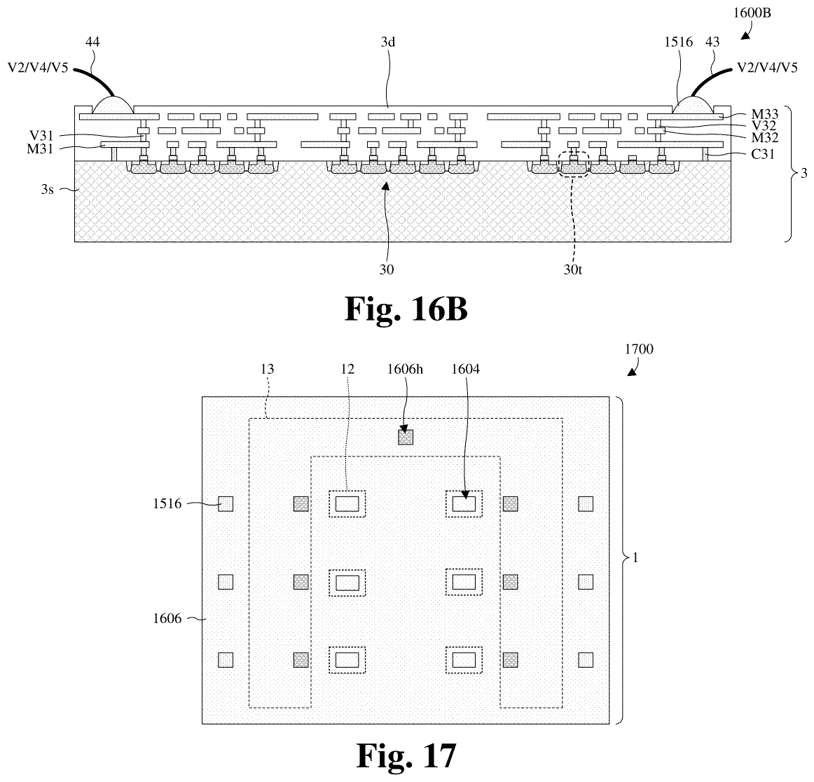

With reference to FIG. 16A, a cross-sectional view 1600A of some embodiments of the first IC die 1 and the second IC die 2 in the biosensor of FIG. 15 is provided. The biosensor includes an array of pixels, each pixel being as in any one or combination of FIGS. 12, 13A-13G, and 14. The first and second IC dies 1, 2 are vertically stacked with. The first IC die 1 comprises a semiconductor substrate 1s accommodating BioFETs 12, whereas the second IC die 2 comprises a semiconductor substrate 2s accommodating pixel circuits 20.

The first interconnect structure 41 is between the first and second IC dies 1, 2 and corresponds to a bond structure. The bond structure includes a plurality of first conductive bond layers 411 and a plurality of first conductive bond vias 412 in a dielectric structure 1d of the first IC die 1 and further includes a plurality of second conductive bond layers 413 and a plurality of second conductive bond vias 414 in a dielectric structure 2d of the second IC die 2. The plurality of first conductive bond layers 411 are connected to the plurality of second conductive bond layers 413. The plurality of first conductive bond layers 411 and the plurality of second conductive bond layers 413 may be bonded by metal-to-metal bonding, whereas surrounding dielectric layers 1d and 2d may be bonded by dielectric-to-dielectric bonding.

The first IC die 1 includes a plurality of conductive wire levels M11, M12, M13, M14 and one or more conductive via levels V11, V12, V13 in the dielectric structure 1d of the first IC die 1. Although FIG. 16A shows four conductive wire levels and three conductive via level, more conductive wire levels and/or more conductive via levels are amenable. The first IC die 1 further includes a plurality of conductive contacts C11 in the dielectric structure 1d. The plurality of conductive contacts C11 electrically couple conductive wire level M11 to the BioFETs 12 and to a bulk of the semiconductor substrate 1s of the first IC die 1.

The BioFETs 12 are in the semiconductor substrate 1s of the first IC die 1 and further include channel regions C₁₂ and source/drain regions S₁₂, D₁₂ in the semiconductor substrate 1s. The reference electrode 13 is shared amongst the BioFETs 12 and is formed over the semiconductor substrate 1s, separated from the semiconductor substrate 1s by a passivation layer 1602. In alternative embodiments, the reference electrode 13 is external to the semiconductor structure of FIG. 16A and/or is individual to the BioFETs 12.

The passivation layer 1602 forms sensing wells 1604, which are individual to and respectively overlie the BioFETs 12. Further, the sensing wells 1604 are lined by a sensing layer 1606 configured to bind with molecules carried in a fluid. Such molecules include, for example, DNA, proteins, cells, and so. The binding triggers the release of ions into the fluid, which alters channel conductivity of the BioFETs 12 and provides measurable signals indicative of the presence and quantity of bound bioentities. The sensing wells 1604 underlie fluidic channels 1520 configured to carry the fluid and formed by the channel structure 1522, which overlies the sensing layer 1606. Further, in some embodiments, the sensing layer 1606 has holes 1606h exposing the reference electrode 13 to the fluidic channels 1520.

The second IC die 2 includes a plurality of conductive wire levels M21, M22, M23, M24 and one or more conductive via levels V21, V22, V23 in the dielectric structure 2d of the second IC die 2. Although FIG. 16A shows four conductive wire levels and three conductive via level, the second IC die 2 may include more conductive wire levels and/or more conductive via levels. The second IC die 2 further includes a plurality of conductive contacts C21 in the dielectric structure 2d. The conductive contacts C21 connect conductive wire level M21 to a bulk of the semiconductor substrate 2s of the second IC die 2 and to the pixel circuits 20.

The pixel circuits 20 comprise a plurality of transistors 20t, which correspond to the support transistors 24 and the select transistors 25 previously discussed. The plurality of transistors 20t may, for example, each be connected to conductive wire level M21 by the plurality of conductive contacts C21.

The BioFETs 12 and the pixel circuits 20 are interconnected by the wire and via levels (e.g., conductive wire level M21, via level V11, etc.) and the first interconnect structure 41 to form the pixel array. Each pixel PX includes a BioFET 12 and a pixel circuit 20 and may, for example, be as in any one or combination of FIGS. 12, 13A-13G, and 14.

The first IC die 1 further includes bump structures 1516 extending through the passivation layer 1602 and the semiconductor substrate 1s of the first IC die 1. The bump structures 1516 electrically couple wire bond structures 43, 44 to conductive wire level M11. Through these wire bond structures, the first and second IC dies 1, 2 receive various voltages, signals, and so on. Note that because FIG. 16A is a cross-sectional view 1600A, there may be additional wire bond structures outside of cross-sectional view 1600A.

With reference to FIGS. 16B, a cross-sectional view 1600B of some embodiments of the third IC die 3 in the biosensor of FIG. 15 is provided.

The third IC die 3 includes a plurality of conductive wire levels M31, M32, M33 and a plurality of conductive via levels V31, V32 in the dielectric structure 3d of the third IC die 3. Although FIG. 16B shows three conductive wire levels and two conductive via levels, the third IC die 3 may include more conductive wire levels and/or more conductive via levels. The third IC die 3 further includes a plurality of conductive contacts C31.

The plurality of conductive contacts C31 are in the dielectric structure 3d of the third IC die 3 and connect conductive wire level M31 to a bulk of the semiconductor substrate 3s of the third IC die 3 and to the ASIC 30. The ASIC 30 comprises individual transistors 30t, which form the ADC 31, the TIA 33, and the controller 34 previously discussed and may each be connected to conductive wire level M31 by the plurality of conductive contacts C31.

The third IC die 3 further includes bump structures 1516 extending through into the dielectric structure 3d of the third IC die 3 to conductive wire level M33 (e.g., a topmost wire level). The bump structures 1516 electrically couple wire bond structures 43, 44 to conductive wire level M33. Through these wire bond structures, the third IC die 1 receives various voltages, signals, and so on and outputs various voltages, signals and so on to the first and second IC dies 1, 2. Note that because FIG. 16B is a cross-sectional view 1600B, there may be additional wire bond structures outside of cross-sectional view 1600B.

As previously discussed, the BioFETs 12 are configured to receive the first reference voltage V1. In FIG. 16A, the biosensor is configured to receive the first reference voltage V1 via a wire bond structure. Conductive features (e.g., wires, vias, contacts, etc.) of the first IC die 1 then pass the first reference voltage V1 to the semiconductor substrate 1s of the first IC die 1 and/or to the BioFETs 12 (e.g., to sources S12).

Also, as previously discussed, the pixel circuit 20 and the ASIC 30 are configured to receive the second reference voltage V2. In FIGS. 16A and 16B, the pixel circuit 20 and the ASIC 30 are configured to receive the second reference voltage V2 via corresponding wire bond structures. Conductive features (e.g., wires, vias, contacts, interconnect structures, etc.) in the first and second IC dies 1, 2 pass the second reference voltage V2 to the semiconductor substrate 2s of the second IC die 2. The semiconductor substrate 2s of the second IC die 2 forms one or more conductive paths to pass the second reference voltage V2 to the transistors 20t of the pixel circuit 20 (e.g., bodies of the transistors 20t).

Similar to the first and second IC die 1,2, conductive features (e.g., wires, vias, contacts, interconnect structures, etc.) in the third IC die 3 pass the second reference voltage V2 to the semiconductor substrate 3s of the third IC die 3. The semiconductor substrate 3s of the third IC die 3 forms one or more conductive paths to pass the second reference voltage V2 to the transistors 30t of the ASIC 30 (e.g., bodies of the transistors 30t).

With reference to FIG. 17, a plan view 1700 of some embodiments of the first IC die 1 of FIG. 16A is provided in which the reference electrode 13 and the BioFETs 12 are shown in phantom. The reference electrode 13 is shared by the BioFETs 12 and has an inverted U-shaped profile. Alternatively, the BioFETs 12 may have individual reference electrodes for the BioFETs 12 and/or the reference electrode 13 may have some other suitable shape. The BioFETs 12 are arranged in three rows and two columns. However, there may be more or less rows and more or less columns. Each BioFET 12 has its own sensing well 1604 and is proximate to its own hole 1606h in the sensing layer 1606. As noted above, such holes expose the reference electrode 13. A plurality of bump structures 1516 are arranged around the periphery of the first IC die to receive voltages, signals, and so on from outside the biosensor and/or from the ASIC 30.

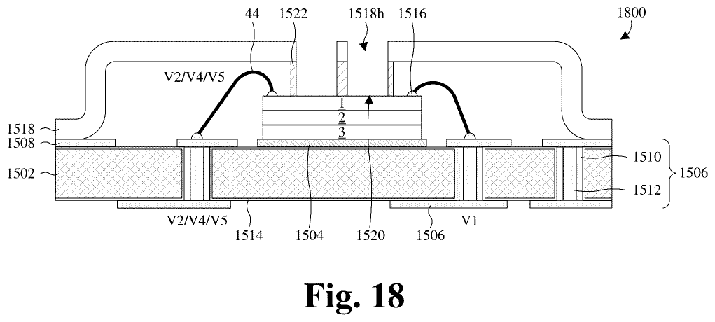

With reference to FIG. 18, a cross-sectional view 1800 of some alternative embodiments of the biosensor of FIG. 15 is provided in which the third IC die 3 is stacked with and electrically coupled to the first and second IC dies 1, 2. Further, the second IC die 2 is between the first and third IC dies 1, 3. As should be appreciated, this stacked structure is similar to the stacked structure described for the image sensor of FIG. 4.

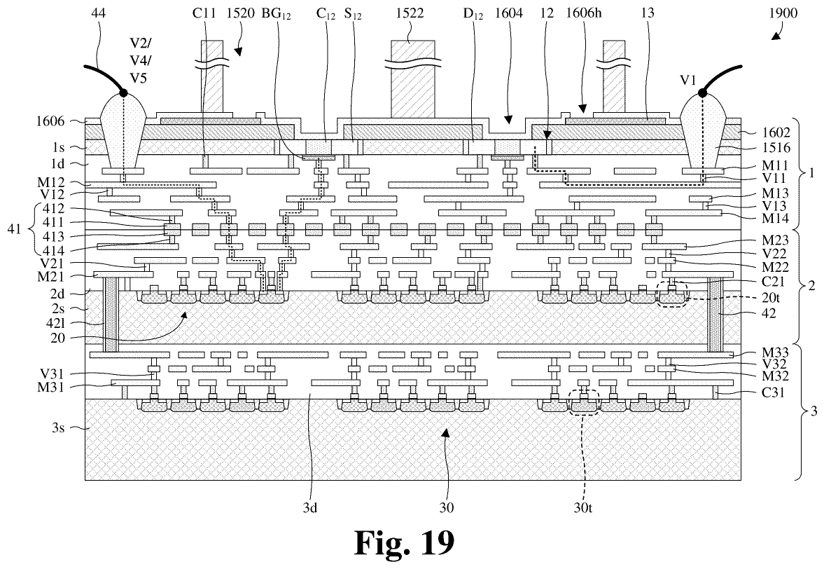

With reference to FIG. 19, a cross-sectional view 1900 of some embodiments of the first, second, and third IC dies 1-3 in the biosensor of FIG. 18 is provided. The first, second, and third IC dies 1-3 are similar to the first, second, and third IC dies 1-3 in FIGS. 16A and 16B, except that the third IC die 3 is now bonded to the second IC die 2. Further, the third IC die 3 is electrically coupled to the second IC die 2 by a second interconnect structure 42.

The second interconnect structure 42 corresponds to a plurality of conductive through vias. The plurality of conductive through vias extend through the semiconductor substrate 2s of the second IC die 2 and are separated from the semiconductor substrate 2s by dielectric liners 421. The conductive through vias may be copper, gold, aluminum, or the like.

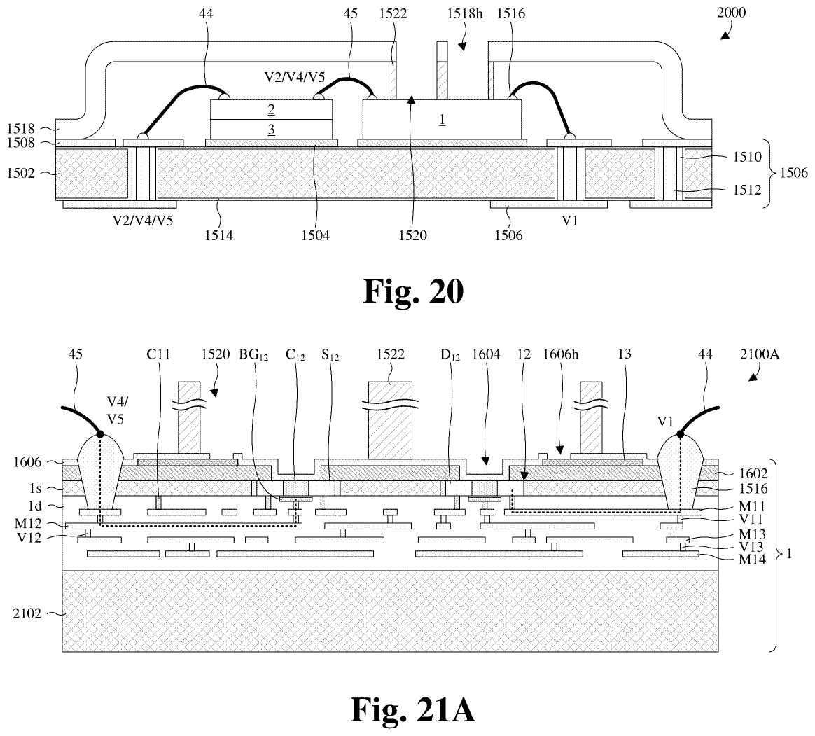

With reference to FIG. 20, a cross-sectional view 2000 of some alternative embodiments of the biosensor of FIG. 15 is provided in which the second and third IC dies 2, 3 are stacked together and laterally offset from the first IC die 1. Further, the first IC die 1 is electrically coupled to the second and third IC dies 2, 3 by an internal wire bond structure 45.

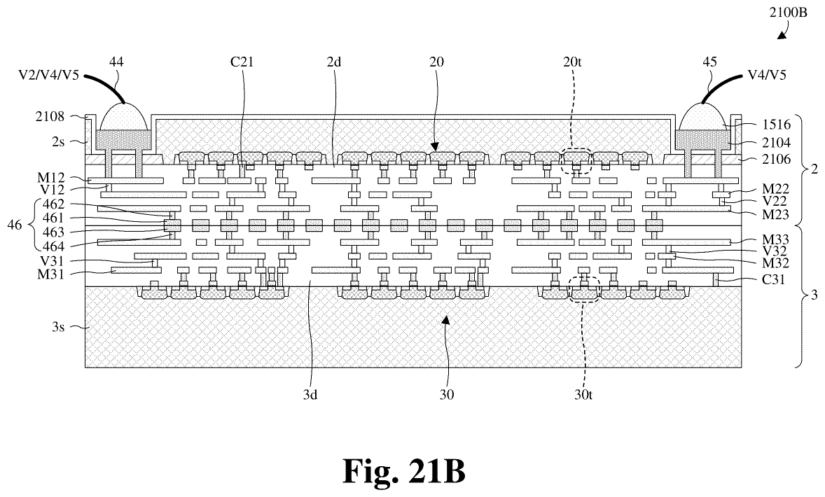

With reference to FIG. 21A, a cross-sectional view 2100A of some embodiments of the first IC die 1 in the biosensor of FIG. 20 is provided. The first IC die 1 is similar to the first IC die 1 in FIG. 16A, except that that first IC die 1 is now bonded to a carrier substrate 2102 rather than the second IC die 2. The carrier substrate 2102 may, for example, be or comprise a silicon substrate or some other suitable type of substrate.

With reference to FIG. 21B, a cross-sectional view 2100B of some embodiments of the second and third IC dies 2, 3 in the biosensor of FIG. 20 is provided. The second and third IC dies 2, 3 are similar to the second and third IC dies 2, 3 in FIGS. 16A and 16B, respectively. However, the second IC die 2 is vertically flipped and bonded to and electrically coupled to the third IC dies 2, 3 via a third interconnect structure 46.

The third interconnect structure corresponds to a bond structure. The bond structure comprises a plurality of first conductive bond layers 461 and a plurality of first conductive bond vias 462 in a dielectric structure 2d of the second IC die 2 and further includes a plurality of second conductive bond layers 463 and a plurality of second conductive bond vias 464 in a dielectric structure 3d of the third IC die 3.

The plurality of first conductive bond layers 461 are connected to the plurality of second conductive bond layers 463. The plurality of first conductive bond layers 461 and the plurality of second conductive bond layers 463 may be bonded by metal-to-metal bonding, whereas surrounding dielectric layers 2d and 3d may be bonded by dielectric-to-dielectric bonding. Conductive wire level M23 is connected to the first conductive bond vias 462, and conductive wire level M33 is connected to the second conductive bond vias 464.

A plurality of conductive pads 2104 are inset into the semiconductor substrate 2s of the second IC die 2 and have individual legs or protrusions extending to conductive wire level M23. The individual legs or protrusions extend through a trench isolation structure 2106 and a passivation layer 2108, the latter of which separates the plurality of conductive pads 2104 from the semiconductor substrate 2s of the second IC die 2.

A plurality of bump structures 1516 are on the plurality of conductive pads 2104 to electrically couple the plurality of conductive pads to wire bond structures 44, 45. Via the bump structures 1516, the plurality of conductive pads 2104, and the wire bond structures 44, 45, the second and third IC dies 2, 3 may receive voltages, signals, and so and an may pass voltages, signals, and so to the first IC die 1. The bump structures 1516 may, for example, be solder bumps and/other suitable types of bump structures.

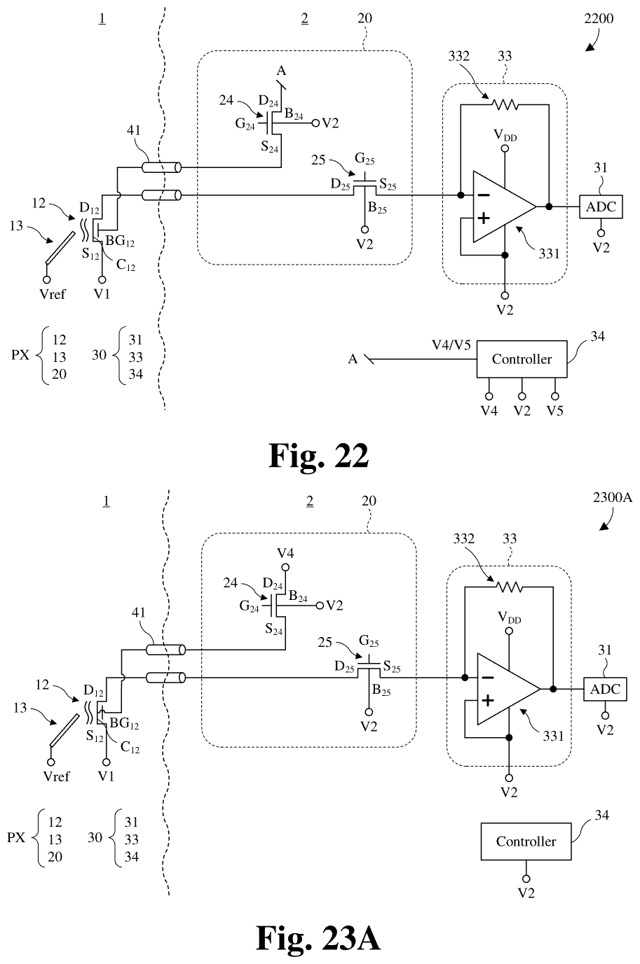

With reference to FIG. 22, a circuit diagram 2200 of some embodiments of a biosensor that spans two IC dies, according to aspects of the present disclosure, is provided. The biosensor is similar to the biosensor of FIG. 12. However, the pixel circuit 20 and the ASIC 30 are both in the second IC die 2 and the third IC die 3 is omitted. Because the pixel circuit 20 and the ASIC 30 have the same reference voltage (e.g., voltage V2), variations in reference voltage are the same in the pixel circuit 20 and the ASIC 30. As a result, noise is reduced and the SNR of the ADC 31 is enhanced. Further, because the BioFET 12 has the first reference voltage V1, which is less than the second reference voltage V2, the voltage across the BioFET 12 may be larger than it would otherwise be and sensitivity may be enhanced.

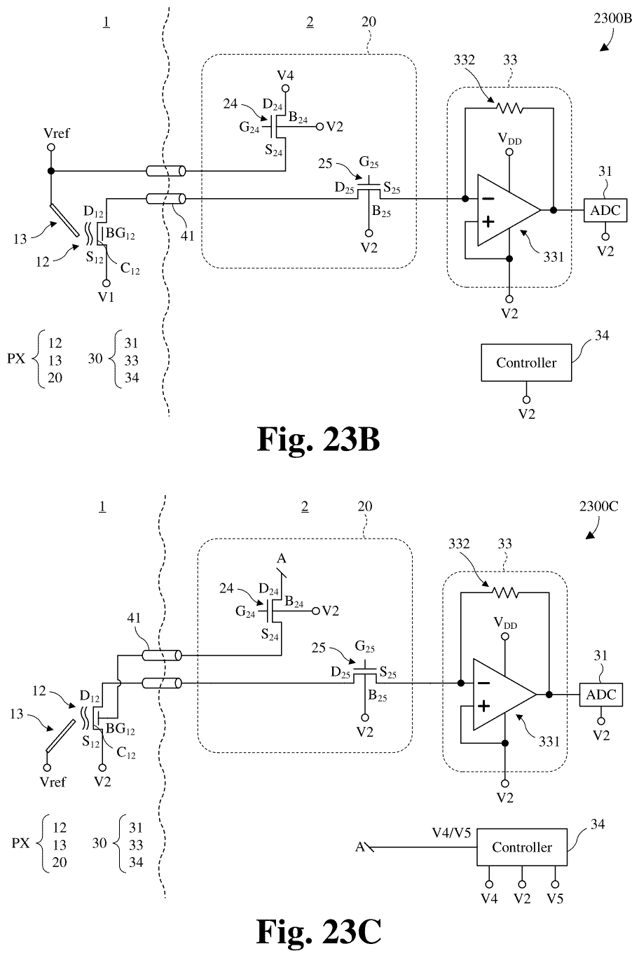

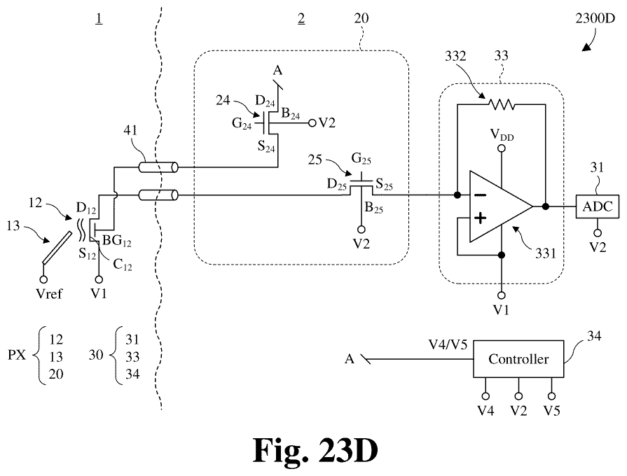

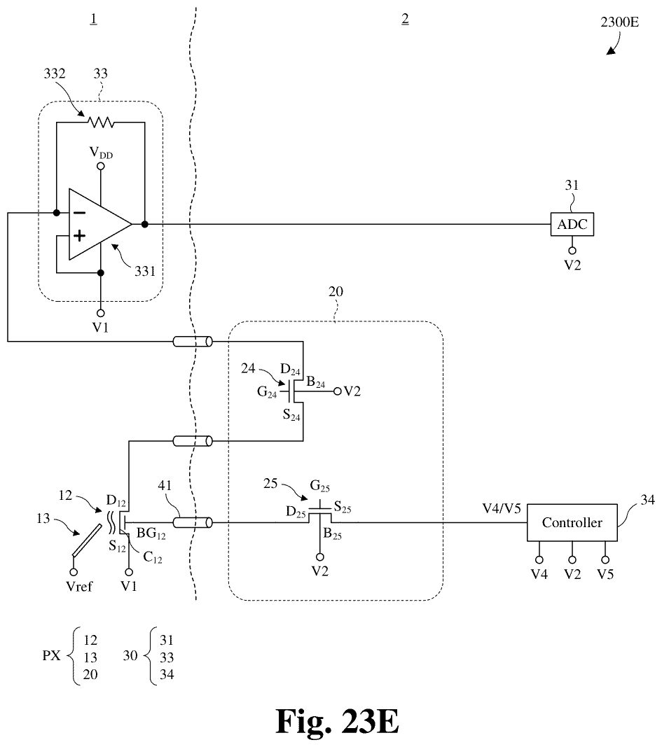

With reference to FIGS. 23A-23E, various circuit diagrams 2300A-2300E of some alternative embodiments of the biosensor of FIG. 22 are provided. FIGS. 23A and 23B are similar respectively to FIGS. 13A and 13B, FIG. 23C is similar to FIG. 13D, and FIGS. 23D and 23E are similar respectively to FIGS. 13F and 13G. However, the pixel circuit 20 and the ASIC 30 are in the second IC die 2 and the third IC die 3 is omitted.

In FIG. 23A, the support transistor 24 is electrically coupled to the back gate BG₁₂ of the BioFET 12 to repel charge away from the channel C₁₂ of the BioFET 12 between sensing cycles. In FIG. 23B, the support transistor 24 is electrically coupled to the reference electrode 13 to repel charge away from the channel C₁₂ of the BioFET 12 between sensing cycles.

In FIG. 23C, the BioFET 12 has the same reference voltage as the pixel circuit 20 and the ASIC 30. For example, the second terminal (e.g., the source S12) and individual transistor bodies of the pixel circuit 20 and the ASIC 30 may be configured to receive the second reference voltage V2 and may hence be electrically coupled (e.g., shorted together).

In FIGS. 23D and 23E, the TIA 33 is further configured to receive the first voltage V1, instead of the second voltage V2, at its reference terminal. Further, the TIA 33 is in the second IC die 2 in FIG. 23D and is in the first IC die 1 in FIG. 23E.

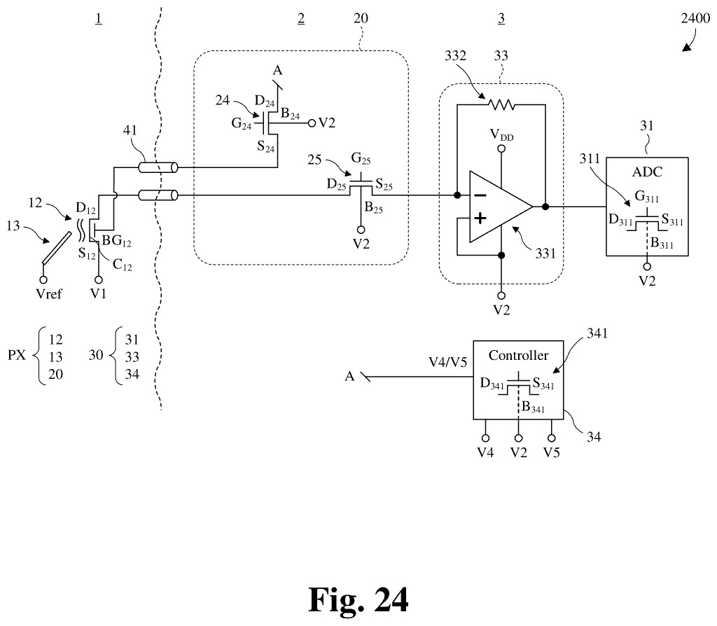

With reference to FIG. 24, a circuit diagram 2400 of some embodiments of the biosensor of FIG. 22 is provided in which the controller 34 and the ADC 31 further comprise individual transistors. The ADC 31 comprises a plurality of transistors 311 (only one of which is shown) that are interconnected to implement functions of the ADC 31. Similar to the ADC 31, the controller 34 comprises a plurality of transistors 341 (only one of which is shown) that are interconnected to implement functions of the controller 34. Further, individual bodies of the transistors 311 of the ADC 31 and the transistors 341 of the controller are configured to receive the second reference voltage V2 and are electrically coupled (e.g., shorted) together.

While not shown, the operational amplifier 331 of the TIA 33 may also comprise individual transistors that are interconnected to implement functions of the operational amplifier 331. These transistors may be similar to the transistors of the ADC 31 and the controller 34 and may hence have individual bodies configured to receive the second reference voltage V2.

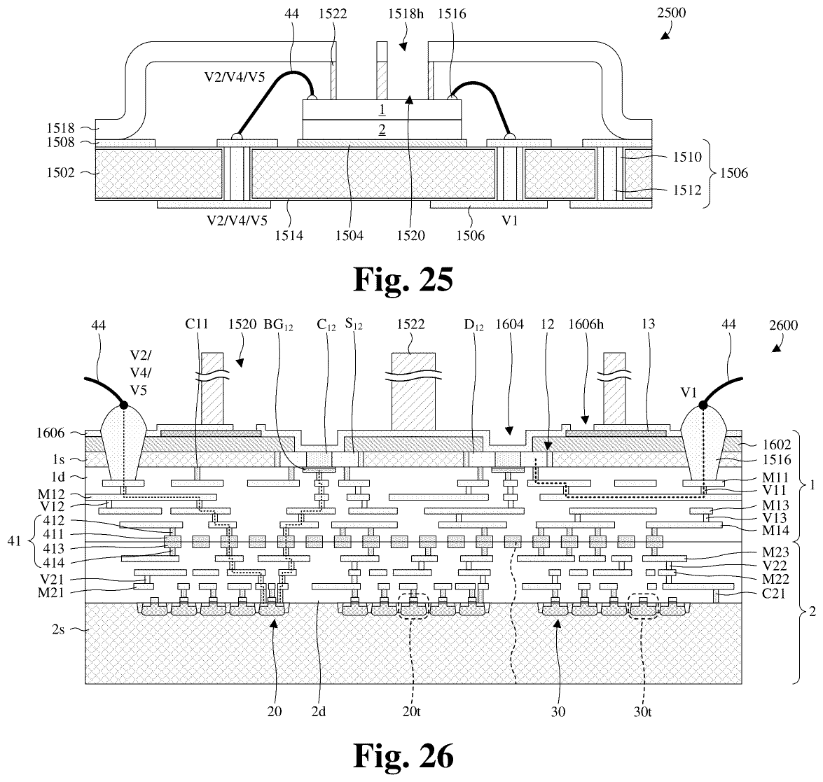

With reference to FIG. 25, a cross-sectional view 2500 of some embodiments of the biosensor of FIG. 22 is provided. The biosensor is similar to FIG. 15, except that the third IC chip 3 is omitted. Further, the ASIC 30 (not shown) is in the second IC die 2.

With reference to FIG. 26, a cross-sectional view 2600 of some embodiments a first IC die 1 and a second IC die 2 in the biosensor of FIG. 25 is provided. The first and second IC dies 1, 2 similar to the first and second IC dies 1, 2 in FIG. 16A, except that that pixel circuits 20 and the ASIC 30 are both in the second IC die 2.

While FIGS. 25 and 26 illustrate the first and second IC dies 1, 2 as being stacked, the first and second IC dies 1, 2 may alternatively be laterally spaced from each other. For example, similar to how the third IC die 3 is laterally spaced from the first and second IC dies 1, 2 in FIG. 15, the first and second IC dies 1, 2 may be laterally spaced.

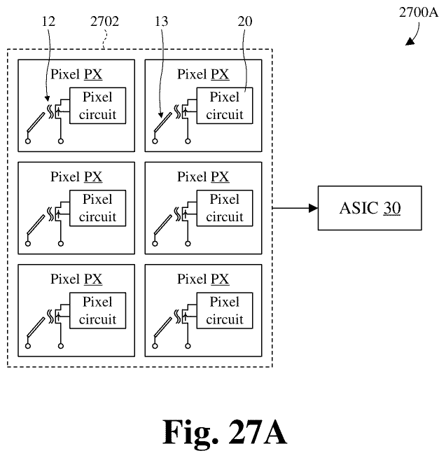

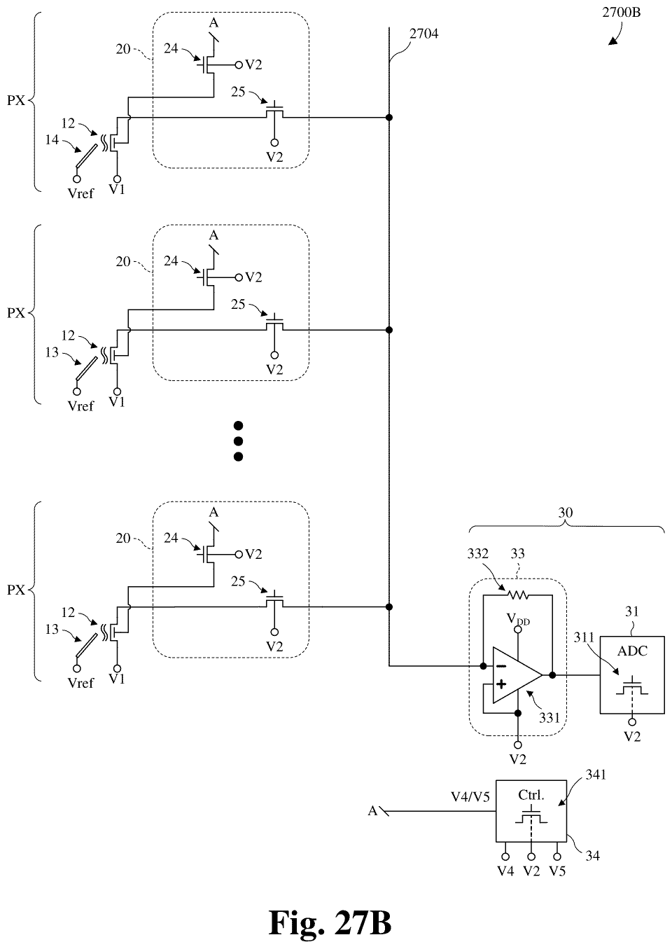

With reference to FIG. 27A, a block diagram 2700A of some embodiments of a biosensor comprising a plurality of pixels PX, each as in any one or combination of FIGS. 12, 13A-13G, 14, 15, 16A, 16B, 17-20, 21A, 21B, 22, 23A-23E, and 24-25, is provided. The plurality of pixels PX are in a plurality of rows and a plurality or columns to form a pixel array 2702. For example, three rows and two columns are illustrated. However, there may be more or less rows and/or more or less columns in alternative embodiments.

The plurality of pixels PX comprise individual BioFETs 12 and individual pixel circuits 20. Further, the plurality of pixels PX are shown as having individual reference electrodes 13 but may share a common reference electrode 13 in alternative embodiments. Further yet, the plurality of pixels PX share the ASIC 30 and are each electrically coupled to the ASIC 30. Therefore, there may be only one ASIC 30 in at least some embodiments. As above, the BioFETs 12 are in the first IC die 1 with the first reference voltage V1, and the pixel circuits 20 are in the second IC die 2 with the second reference voltage V2. Further, the ASIC 30 is at least partially in a second or third IC die 2, 3 with the second reference voltage V2.

With reference to FIG. 27B, a circuit diagram 2700B of the pixel array 2702 of FIG. 27A is provided. The pixels PX are individually connected to a conductive line 2704 (e.g., via sources of select transistors 25 in the individual pixels PX). The conductive line 2704 extends to the ASIC 30 and electrically couples with the TIA 33 and the ADC 31.

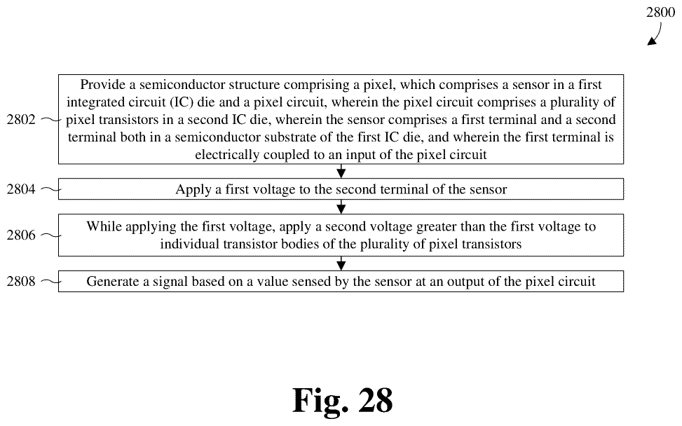

With reference to FIG. 28, a block diagram 2800 of some embodiments of a method of use according to aspects of the present disclosure. The method of use is common to both the images sensors (e.g., the image sensor of FIG. 1) and the biosensors (e.g., the biosensor of FIG. 12). Further, the method is applicable to other pixel-based devices comprising a sensor and a pixel circuit electrically coupled to the sensor.

At Act 2802, a semiconductor structure comprising a pixel is provided. The semiconductor structure comprises a sensor in a first IC die and a pixel circuit. The pixel circuit comprises a plurality of pixel transistors in a second IC die. The sensor comprises a first terminal and a second terminal both in a semiconductor substrate of the first IC die, and the first terminal is electrically coupled to an input of the pixel circuit.

At Act 2804, a first voltage is applied to the second terminal of the sensor.

At Act 2806, while applying the first voltage, a second voltage greater than the first voltage is applied to individual transistor bodies of the plurality of pixel transistors.

At Act 2808, a signal based on a value sensed by the sensor is generated at an output of the pixel circuit.

In some embodiments, the sensor is a pinned photodetector. Such embodiments may, for example, arise when the method of use is applied to the image sensor in any one of FIGS. 1 to 11B. In other embodiments, the sensor is a BioFET. Such other embodiments may, for example, arise when the method of use is applied to the biosensor in any one of FIGS. 12 to 27B.

In some embodiments in which the sensor is a BioFET, the method of use further includes applying a voltage to a reference electrode of the BioFET, a channel of the BioFET, or a back gate of the BioFET between sensing cycles. A sensing cycle may be regarded as acts 2802 to 2808. The voltage repels ions and/or charges near the channel that may linger from previous sensing cycles and skew measurements with the BioFET. For negative ions or charges, the voltage may be negative. For positive ions or charges, the voltage may be positive.

In some embodiments in which the sensor is a BioFET, the method of use further includes applying a voltage to the back gate of the BioFET during a sensing cycle. As above, a sensing cycle may be regarded as acts 2802 to 2808. The voltage attracts ions and/or charges to channel to enhance sensitivity of the BioFET. For negative ions or charges, the voltage may be positive. For positive ions or charges, the voltage may be negative.

While the block diagram 2800 of FIG. 28 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

While the present disclosure focused on image sensors and biosensors, it is to be appreciated that the aforementioned arrangements and solutions are applicable to other device types. For example, circuit components can be shifted amongst different IC dies, and/or additional voltages can be added to other device types, to reduce noise and/or enhance performance. Such other device types include, for example, Microelectromechanical Systems (MEMS) microphones, three-dimensional (3D) memory, 3D fabric, photonics, and so on.

This approach of biasing stacked substrates with different voltages is applicable to 3D memory structures (e.g., high bandwidth memory, HBM, and so on). These structures may include vertically stacked memory dies (e.g., DRAM or the like) and a controller die, with independent supply voltages applied to each. Independent ground levels can be maintained, and periphery circuitry (e.g., sense amplifiers, data buffers, decoders, and so on) can be manufactured on a separate substrate and biased with the same voltage as the controller die. This enables cancellation of ground-level variations, reducing noise and improving SNR.

Similarly, this approach can be applied to 3D MEMS structures comprising functional dies (e.g., sensors, logic controllers, thermal dissipaters, power controllers, and so on) with independently biased substrates. Maintaining independent ground levels allows for noise reduction. Input/output (I/O) devices of a sensor die can be separately manufactured on another substrate and biased with the same voltage as the controller die's I/O devices, further enabling ground-level variation cancellation and SNR improvement.

Reducing the size of functional dies (e.g., X-Y area) is achievable by manufacturing I/O devices on a separate substrate or integrating them into the controller die. This also increases the utility area of the functional die by removing the I/O devices from its footprint.

In some embodiments, a MEMS structure is designed for sound detection. This structure comprises a substrate, a semiconductor die for control and signal processing, a sensor incorporating a transducer, and a protective lid. Sound waves enter a cavity defined by the substrate and lid, causing a membrane within the sensor to vibrate. This vibration is converted into an electrical signal by a piezoelectric component and transmitted to the semiconductor die.

The substrate incorporates multiple conductive layers, vias, and pads to facilitate electrical connections and voltage delivery. The semiconductor die operates with a first bias voltage, establishing its grounding level. This voltage can also be used to power or ground the sensor. The lid is grounded through the substrate's conductive layers.

A challenge in transducer design is the accumulation of electrostatic charges on the vibrating membrane, leading to stiction and noise. To address this, the disclosed structure incorporates additional wiring and a second bias voltage applied to the transducer. This second voltage, differing from first bias voltage, releases the accumulated charges, minimizing stiction and improving signal clarity. The second bias voltage can be applied continuously or intermittently, depending on the application of the MEMS structure.

By carefully managing voltage levels and addressing the issue of electrostatic charges, this MEMS structure provides a robust and accurate solution for sound detection and other sensing applications. The principles outlined in this disclosure are applicable to a wide range of MEMS devices and can be adapted to enhance performance and minimize noise.

In some embodiments, a 3D memory structure, such as, for example, a HBM, comprises vertically stacked memory dies and a controller die. Independent supply voltages are applied to the substrates of both the memory dies and the controller die. Periphery circuitry, such as sense amplifiers decoders, and so on, is manufactured on a separate substrate or integrated directly into the controller die. This circuitry is biased with the same voltage as the controller die, effectively canceling out ground level variations and reducing noise, thereby improving the SNR of the controller.

In some embodiments, the memory dies and controller die are fabricated using different technology nodes or by different manufacturers and are biased with differing grounding levels. Dedicated transmission paths ensure appropriate voltage delivery to each component. The memory dies may, for example, utilize a negative grounding voltage, while the controller's logic devices may, for example, operate with a zero-volt ground. By relocating the periphery circuitry, the size of the memory dies can be reduced, increasing the usable area and overall efficiency of the 3D memory structure.

In some embodiments, a 3D fabric, such as Chip-on-Wafer-on-Substrate (CoWoS) or Integrated Fan-Out (InFO), utilizes independent grounding voltages for different dies—including memory, logic, and sensor dies—to enhance performance and address variations arising from differing manufacturing processes or suppliers.

Memory dies may, for example, be supplied with a negative grounding voltage to enhance performance, while logic and I/O dies may, for example, operate with a zero-volt ground. Sensor dies, such as those with analog components, may also utilize a negative grounding voltage to improve dynamic range. Multiple dies are interconnected via an interposer or redistribution layer, with dedicated transmission paths ensuring each die receives its designated grounding voltage. This approach mitigates ground tracking issues and allows for customized voltage levels tailored to each die's specific requirements. Further, by independently controlling the grounding voltages, the 3D fabric can enhance performance, reduce noise, and accommodate dies manufactured using different technology nodes or by different suppliers.

In some embodiments, a photonic device utilizes independent biasing of different substrates to enhance performance. This approach is applicable to optical communication systems and other photonic devices. The system comprises an optical source, a modulator, a receiver, and associated drivers and processors distributed across two substrates. The first substrate houses the optical components, while the second substrate contains the control electronics. The modulator includes multiple modulators (e.g., ring modulators or the like) with independently tunable resonant wavelengths. These wavelengths are adjusted using a combination of electrical and thermal drivers.

Independent grounding voltages are applied to the two substrates, allowing for customized biasing of the optical and electronic components. This enables enhancement of performance metrics such as dynamic range and free spectral range. In some embodiments, the modulator incorporates PIN phase shifters and metal heaters to control the optical signal. Independent biasing of these components allows for fine-tuning of the modulator's characteristics. By strategically applying different bias voltages to the optical and electronic components, the photonic device can achieve improved performance, reduced noise, and enhanced signal integrity.

In some embodiments, the present disclosure relates to a semiconductor structure, including: a first IC die including a first semiconductor substrate; a second IC die including a second semiconductor substrate; and a pixel including a sensor in the first IC die and a pixel circuit, wherein the pixel circuit includes a plurality of pixel transistors in the second IC die, the sensor includes a first terminal and a second terminal both in the first semiconductor substrate, the first terminal is electrically coupled to an input of the pixel circuit, and the second terminal is electrically isolated from individual bodies of the plurality of pixel transistors. In some embodiments, the sensor includes a photodetector in the first semiconductor substrate, wherein the pixel circuit further includes a transfer transistor in the first IC die and separating the sensor from a remainder of the pixel circuit. In some embodiments, the semiconductor structure further includes: a third IC die including an ADC, which has an input electrically coupled to an output of the pixel circuit; and a current source having a first terminal electrically coupled to the output of the pixel circuit and the input of the ADC and further having a second terminal electrically isolated from the second terminal of the sensor. In some embodiments, the current source is in the first IC die. In some embodiments, the sensor includes BioFET. In some embodiments, the semiconductor structure further includes: a third IC die including an ADC; and a TIA electrically coupled from an output of the pixel circuit to an input of the ADC, wherein the TIA is in the first IC die. In some embodiments, the semiconductor structure further includes: a third IC die including an ADC and a TIA electrically coupled from an output of the pixel circuit to an input of the ADC. The semiconductor structure further includes: a third IC die including a controller that is configured to selectively pass one of multiple different voltages to a channel of the BioFET or a back gate of the BioFET.

In other embodiments, the present disclosure relates to another semiconductor structure, including: a photodetector on a first semiconductor substrate; a pixel circuit including a transfer transistor on the first semiconductor substrate and a plurality of pixel transistors on a second semiconductor substrate, wherein the transfer transistor is electrically coupled to a cathode of the photodetector and separates the photodetector from the plurality of pixel transistors; and an ADC that is on the second semiconductor substrate and that is electrically coupled to an output of the pixel circuit, wherein the plurality of pixel transistors and a transistor of the ADC have individual transistor bodies electrically coupled together and isolated from an anode of the photodetector. In some embodiments, the semiconductor further includes a current source on the first semiconductor substrate and electrically coupled from the output of the pixel circuit to the anode of the photodetector. In some embodiments, the semiconductor further includes a current source on the second semiconductor substrate and electrically coupled from the output of the pixel circuit to the anode of the photodetector. In some embodiments, the semiconductor further includes a current source on the second semiconductor substrate, wherein the current source has a first terminal electrically coupled to the output of the pixel circuit and a second terminal electrically isolated from the individual transistor bodies. In some embodiments, the semiconductor further includes a current source on the second semiconductor substrate and including an additional transistor and a capacitor, wherein the additional transistor has a drain electrically coupled to the output of the pixel circuit, wherein the capacitor is electrically coupled from a gate of the additional transistor to a source of the additional transistor, and wherein the source of the additional transistor and a body of the additional transistor are electrically coupled together and electrically isolated from the individual transistor bodies. In some embodiments, the plurality of pixel transistors includes a source-follower transistor having a gate electrically coupled to a drain of the transfer transistor and further includes a select transistor electrically coupled from the source-follower transistor to the output of the pixel circuit.

In yet other embodiments, the present disclosure relates to a method, including: providing a semiconductor structure including a pixel, which includes a sensor in a first IC die and a pixel circuit, wherein the pixel circuit includes a plurality of pixel transistors in a second IC die, wherein the sensor includes a first terminal and a second terminal both in a semiconductor substrate of the first IC die, and wherein the first terminal is electrically coupled to an input of the pixel circuit; applying a first voltage to the second terminal of the sensor; while applying the first voltage, applying a second voltage greater than the first voltage to individual transistor bodies of the plurality of pixel transistors; and generating a signal based on a value sensed by the sensor at an output of the pixel circuit. In some embodiments, the sensor includes a pinned photodiode, wherein the second terminal of the sensor corresponds to a cathode of the pinned photodiode. In some embodiments, the sensor includes a BioFET, wherein the second terminal of the sensor corresponds to a source or drain region of the BioFET. In some embodiments, the method further includes, before generating the signal, applying a voltage to a back gate of the BioFET or a channel of the BioFET to clear charge in a sensing well of the BioFET from proximate the channel of the BioFET. In some embodiments, the method further includes, while generating the signal, applying a voltage to a back gate of the BioFET to attract charge in a sensing well of the BioFET to proximate a channel of the BioFET. In some embodiments, the first voltage is negative and the second voltage is ground.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first integrated circuit (IC) die comprising a first semiconductor substrate;
a second IC die comprising a second semiconductor substrate; and
a pixel comprising a sensor in the first IC die and a pixel circuit,
wherein the pixel circuit comprises a plurality of pixel transistors in the second IC die, the sensor comprises a first terminal and a second terminal both in the first semiconductor substrate, the first terminal is electrically coupled to an input of the pixel circuit, and the second terminal is electrically isolated from individual bodies of the plurality of pixel transistors.

2. The semiconductor structure according to claim 1, wherein the sensor comprises a photodetector in the first semiconductor substrate, and wherein the pixel circuit further comprises a transfer transistor in the first IC die and separating the sensor from a remainder of the pixel circuit.

3. The semiconductor structure according to claim 1, further comprising:
a third IC die comprising an analog-to-digital converter (ADC), which has an input electrically coupled to an output of the pixel circuit; and
a current source having a first terminal electrically coupled to the output of the pixel circuit and the input of the ADC and further having a second terminal electrically isolated from the second terminal of the sensor.

4. The semiconductor structure according to claim 3, wherein the current source is in the first IC die.

5. The semiconductor structure according to claim 1, wherein the sensor comprises a bio field-effect transistor (BioFET).

6. The semiconductor structure according to claim 5, further comprising:
a third IC die comprising an analog-to-digital converter (ADC); and
a transimpedance amplifier (TIA) electrically coupled from an output of the pixel circuit to an input of the ADC, wherein the TIA is in the first IC die.

7. The semiconductor structure according to claim 5, further comprising:
a third IC die comprising an analog-to-digital converter (ADC) and a transimpedance amplifier (TIA) electrically coupled from an output of the pixel circuit to an input of the ADC.

8. The semiconductor structure according to claim 5, further comprising:
a third IC die comprising a controller that is configured to selectively pass one of multiple different voltages to a channel of the BioFET or a back gate of the BioFET.

9. A semiconductor structure, comprising:
a photodetector on a first semiconductor substrate;
a pixel circuit comprising a transfer transistor on the first semiconductor substrate and a plurality of pixel transistors on a second semiconductor substrate, wherein the transfer transistor is electrically coupled to a cathode of the photodetector and separates the photodetector from the plurality of pixel transistors; and
an analog-to-digital converter (ADC) that is on the second semiconductor substrate and that is electrically coupled to an output of the pixel circuit,
wherein the plurality of pixel transistors and a transistor of the ADC have individual transistor bodies electrically coupled together and isolated from an anode of the photodetector.

10. The semiconductor structure according to claim 9, further comprising:
a current source on the first semiconductor substrate and electrically coupled from the output of the pixel circuit to the anode of the photodetector.

11. The semiconductor structure according to claim 9, further comprising:
a current source on the second semiconductor substrate and electrically coupled from the output of the pixel circuit to the anode of the photodetector.

12. The semiconductor structure according to claim 9, further comprising:
a current source on the second semiconductor substrate, wherein the current source has a first terminal electrically coupled to the output of the pixel circuit and a second terminal electrically isolated from the individual transistor bodies.

13. The semiconductor structure according to claim 9, further comprising:
a current source on the second semiconductor substrate and comprising an additional transistor and a capacitor, wherein the additional transistor has a drain electrically coupled to the output of the pixel circuit, wherein the capacitor is electrically coupled from a gate of the additional transistor to a source of the additional transistor, and wherein the source of the additional transistor and a body of the additional transistor are electrically coupled together and electrically isolated from the individual transistor bodies.

14. The semiconductor structure according to claim 9, wherein the plurality of pixel transistors comprises a source-follower transistor having a gate electrically coupled to a drain of the transfer transistor and further comprises a select transistor electrically coupled from the source-follower transistor to the output of the pixel circuit.

15. A method, comprising:
providing a semiconductor structure comprising a pixel, which comprises a sensor in a first integrated circuit (IC) die and a pixel circuit, wherein the pixel circuit comprises a plurality of pixel transistors in a second IC die, wherein the sensor comprises a first terminal and a second terminal both in a semiconductor substrate of the first IC die, and wherein the first terminal is electrically coupled to an input of the pixel circuit;
applying a first voltage to the second terminal of the sensor;
while applying the first voltage, applying a second voltage greater than the first voltage to individual transistor bodies of the plurality of pixel transistors; and
generating a signal based on a value sensed by the sensor at an output of the pixel circuit.

16. The method according to claim 15, wherein the sensor comprises a pinned photodiode, and wherein the second terminal of the sensor corresponds to a cathode of the pinned photodiode.

17. The method according to claim 15, wherein the sensor comprises a bio field-effect transistor (BioFET), and wherein the second terminal of the sensor corresponds to a source or drain region of the BioFET.

18. The method according to claim 17, further comprising:
before generating the signal, applying a voltage to a back gate of the BioFET or a channel of the BioFET to clear charge in a sensing well of the BioFET from proximate the channel of the BioFET.

19. The method according to claim 17, further comprising:
while generating the signal, applying a voltage to a back gate of the BioFET to attract charge in a sensing well of the BioFET to proximate a channel of the BioFET.

20. The method according to claim 15, wherein the first voltage is negative and the second voltage is ground.
